(19) United States
(12) Patent Application Publication
(10) Pub. No.: US 2010/0142729 A1
(43) Pub. Date: Jun. 10, 2010

(54) SOUND VOLUME CORRECTING DEVICE, SOUND VOLUME CORRECTING METHOD, SOUND VOLUME CORRECTING PROGRAM AND ELECTRONIC APPARATUS

(75) Inventor: Masayoshi Noguchi, Chiba (JP)

Correspondence Address: WOLF GREENFIELD & SACKS, P.C., 600 ATLANTIC AVENUE, BOSTON, MA, 02210-2206, US

(73) Assignee: Sony Corporation, Tokyo (JP)

(21) Appl. No.: 12/629,335

(22) Filed: Dec. 2, 2009

(30) Foreign Application Priority Data
Dec. 5, 2008 (JP) 2008-310901

(51) Int. Cl. H03G 3/00

(52) U.S. Cl. 381/107

(57) ABSTRACT

A sound volume correcting device includes: a first component gain control unit configured to control a gain of a main first component signal, which contains a part of a plurality of audio components as a main component, out of input audio signals including the plurality of audio components and outputting the main first component signal; a first component gain control signal generator configured to generate a first component gain control signal for allowing the first component gain control unit to control the gain of the main first component signal in a first gain control way; and an other component output unit configured to output other audio components other than the first component of the input audio signals in a second gain control way different from the first gain control way.

### BACKGROUND OF THE INVENTION

1. Field of the Invention

The present invention relates to a sound volume correcting device, a sound volume correcting method, and a sound volume correcting program, which can be suitably used in a sound output unit of an electronic apparatus such as a television broadcast receiver.

2. Description of the Related Art

When a broadcast channel received by a television broadcast receiver is switched or when plural input devices are switched in an AV center of an audio-visual (AV) system, an output sound volume may be greatly changed due to a level difference between contents.

In this case, it is necessary for a user to adjust the sound volume using a remote controller or the like so as to obtain his preferred sound volume and thus may find it troublesome.

Even with the same contents (for example, on the same broadcast channel or during the same broadcast program), the output sound volume varies depending on a variation between commercial message (CM) breaks or scenes, thereby giving an unpleasant feeling.

Various sound volume correcting techniques have been suggested to solve the above-mentioned problem. A sound volume control method using an AGC (Auto Gain Control) is widely known as an example thereof.

FIG. 28 is a block diagram illustrating the configuration of a sound volume corrector using the AGC. In the example shown in FIG. 28, two left and right channel input audio signals SiL and SiR are corrected in sound volume.

In this example, the two left and right channel input audio signals SiL and SiR are supplied to variation gain amplifiers 1L and 1R of which the gains are variably controlled on the basis of a gain control signal.

The two left and right channel input audio signals SiL and SiR are added to each other by an adder 2. The added output signal from the adder 2 is made to be half the gain by an amplifier 3 and is then supplied to an average level detector 4, and the average level of the added output signal is detected by the average level detector 4.

The average level detected by the average level detector 4 is supplied to a gain control signal generator 5. The gain control signal generator 5 compares the average level from the average level detector 4 with a predetermined reference level, generates a gain control signal so that the difference between both levels is zero using the comparison result, and supplies the generated gain control signal to the variable gain amplifiers 1L and 1R.

In the variable gain amplifiers 1L and 1R, the gain is variably controlled on the basis of the gain control signal from the gain control signal generator 5. In this case, the gains of the two left and right channel input audio signals SiL and SiR are controlled by the variable gain amplifiers 1L and 1R so that the average level of the added output signal from the adder 2 is equal to the reference level.

As a result, two left and right channel output audio signals SoL and SoR obtained from the variable gain amplifiers 1L and 1R are automatically corrected to a constant level of sound volume by adjusting a small sound to be great and a great sound to be small.

Various sound volume correcting methods have been suggested in addition to the sound volume correcting method using the AGC. For example, Japanese Patent No. 3321820 discloses a method of controlling a sound volume within a constant range by controlling a compressor to adjust an output sound level to be smaller than an input sound level when a great level of sound is input.

### SUMMARY OF THE INVENTION

The above-mentioned sound volume correcting method is a method of making a control of sound volume by monitoring the level of the entire audio signals. For example, in the AGC method, when the control of sound volume (gain control) is made using the average level of the entire audio signals as a reference, the control of sound volume is made for all the audio signals, whereby a loud sound can be made to be inaudible or a small sound can be made to be audible.

However, for example, when the channel is switched in receiving a television broadcast, when plural input devices are switched in an AV center, and when CM breaks or scenes are changed, a great level of difference may occur in the audio signals before and after the switch or change.

In this way, when the level of the input audio signal varies greatly, it is difficult to completely suppress the rapid variation in audio signal gain at the level varying point, and the output sound volume level wobbles at the level varying point, thereby giving an unpleasant auditory feeling to listeners.

Particularly, in the above-mentioned sound volume correcting method, since the gains of the entire audio signals are uniformly controlled, there is a problem that the unpleasant feeling resulting from the wobble in sound volume level at the rapid varying point is marked.

It is desirable to provide a sound volume correcting device and a sound volume correcting method, which can reduce an unpleasant feeling by making a wobble in output sound volume level at a level varying point not marked even when the level of an input audio signal greatly varies.

According to an embodiment of the invention, there is provided a sound volume correcting device including: first component gain control means for controlling a gain of a main first component signal, which contains a part of a plurality of audio components as a main component, out of input audio signals including the plurality of audio components and outputting the main first component signal; first component gain control signal generating means for generating a first component gain control signal for allowing the first component gain control means to control the gain of the main first component signal in a first gain control way; and other component output means for outputting other audio components other than the first component of the input audio signals in a second gain control way different from the first gain control way.

According to this configuration, for example, the same gain control as the past control of keeping the output level constant is performed on the main first component signal of the input audio signals, but other components other than the first component are controlled and output in a different gain control way.

Therefore, in the main first component signal, similarly to the past case, a wobble in output sound volume level occurs at a level varying point where the level of the input audio signals greatly vary. However, the wobble in sound volume level can be made not to occur in the other components other than the first component.

Accordingly, when the gain-controlled main first component signal and the other component audio signals other than the first component are auditorily reproduced, the wobble in sound volume level of the main first component signal is masked by the reproduced sound of the other component audio signals other than the first component due to the auditory combination thereof. Accordingly, the wobble in sound volume level at the level varying point is not marked, thereby reducing the unpleasant feeling.

When an audio signal which is obtained by adding the gain-controlled main first component signal to the other component audio signals other than the first component is output as the volume-corrected audio output signal, the wobble in sound volume level at the level varying point is not marked due to the same masking operation, thereby reducing the unpleasant feeling.

According to the above-mentioned embodiment of the invention, since the main first component signal and the other component audio signals other than the first component are output in different gain control ways, the wobble in sound volume level at the level varying point where the level of the input audio signals greatly varies is not marked, thereby reducing the unpleasant feeling.

### BRIEF DESCRIPTION OF THE DRAWINGS

FIG. 1 is a block diagram illustrating a sound volume correcting device according to a first embodiment of the invention.

FIG. 2 is a block diagram illustrating an example of an electronic apparatus employing the sound volume correcting device according to the first embodiment of the invention.

FIGS. 3A to 3F are waveform diagrams illustrating operations of the sound volume correcting device according to the first embodiment of the invention.

FIG. 4 is a block diagram illustrating a configuration of a centered orientation signal generator according to the first embodiment shown in FIG. 1.

FIG. 5 is a block diagram illustrating another configuration of the centered orientation signal generator according to the first embodiment shown in FIG. 1.

FIG. 6 is a block diagram illustrating a partial configuration of the centered orientation signal generator shown in FIG. 5.

FIGS. 7A and 7B are diagrams illustrating the units of the configuration shown in FIG. 6.

FIG. 8 is a diagram illustrating the units of the configuration shown in FIG. 6.

FIG. 9 is a diagram illustrating the units of the configuration shown in FIG. 6.

FIG. 10 is a diagram illustrating the units of the configuration shown in FIG. 6.

FIG. 11 is a diagram illustrating the units of the configuration shown in FIG. 6.

FIG. 12 is a diagram illustrating the units of the configuration shown in FIG. 6.

FIG. 13 is a diagram illustrating the units of the configuration shown in FIG. 6.

FIG. 14 is a block diagram illustrating a sound volume correcting device according to a second embodiment of the invention.

FIG. 15 is a block diagram illustrating a first configuration example of a live sound level correction gain generator according to the second embodiment of the invention.

FIG. 16 is a diagram illustrating the first configuration example of the live sound level correction gain generator.

FIG. 17 is a flowchart illustrating a flow of operations in the first configuration example of the live sound level correction gain generator.

FIGS. 18A to 18F are waveform diagrams illustrating operations of the sound volume correcting device according to the second embodiment of the invention employing the first configuration example of the live sound level correction gain generator.

FIG. 19 is a block diagram illustrating a sound volume correcting device according to a modified example of the second embodiment of the invention employing the first configuration example of the live sound level correction gain generator.

FIG. 20 is a block diagram illustrating a second configuration example of the live sound level correction gain generator according to the second embodiment of the invention.

FIGS. 21A to 21F are waveform diagrams illustrating operations of the sound volume correcting device according to the second embodiment of the invention employing the second configuration example of the live sound level correction gain generator.

FIG. 22 is a block diagram illustrating a third configuration example of the live sound level correction gain generator according to the second embodiment of the invention.

FIGS. 23A to 23F are waveform diagrams illustrating operations of the sound volume correcting device according to the second embodiment of the invention employing the third configuration example of the live sound level correction gain generator.

FIG. 24 is a block diagram illustrating a sound volume correcting device according to another embodiment of the invention.

FIG. 25 is a block diagram illustrating a sound volume correcting device according to another embodiment of the invention.

FIG. 26 is a block diagram illustrating a sound volume correcting device according to another embodiment of the invention.

FIG. 27 is a diagram illustrating another electronic apparatus employing the sound volume correcting device according to the embodiments of the invention.

FIG. 28 is a block diagram illustrating a past sound volume correcting device.

### DESCRIPTION OF THE PREFERRED EMBODIMENTS

Hereinafter, a sound volume correcting device according to preferred embodiments of the invention will be described with reference to the accompanying drawings. In the embodiments, a sound volume correcting device is used as an audio output unit of a television broadcast receiver.

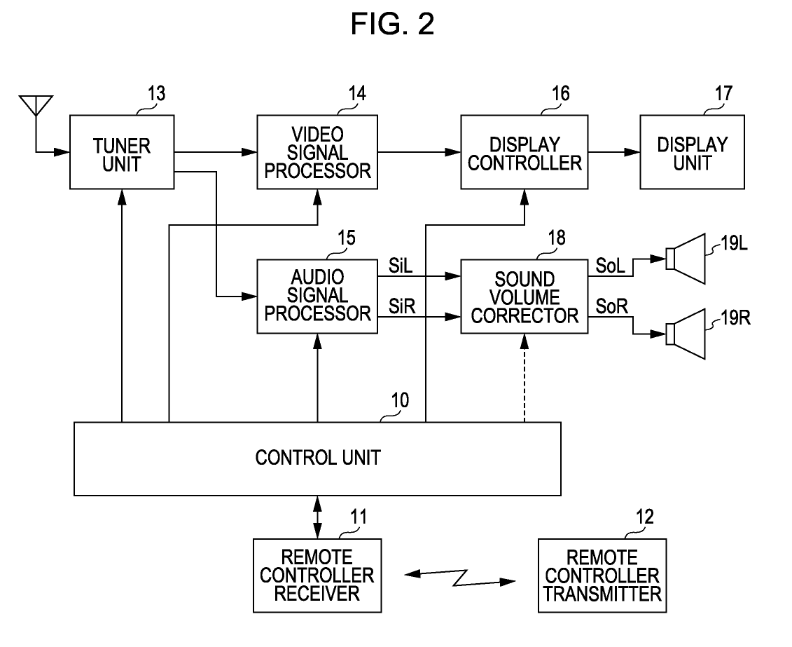

That is, FIG. 2 is a block diagram illustrating the configuration of a television broadcast receiver. The television broadcast receiver shown in FIG. 2 includes a control unit 10 including a micro computer. A remote controller receiver 11 is connected to the control unit 10. The remote controller receiver 11 receives a remote controller signal from a remote controller transmitter 12 and supplies the received remote controller signal to the control unit 10. The control unit 10 makes a control of processes corresponding to the received remote controller signal.

The control unit 10 supplies control signals to the constituent units of the television broadcast receiver and performs processes of receiving a television broadcast signal, reproducing a video thereof, and reproducing an audio.

The tuner unit 13 selects and extracts a signal of a broadcast channel, which is specified by a channel selection control signal corresponding to a user's operating a remote controller and supplied from the control unit 10, from the television broadcast signals. The tuner unit 13 demodulates and decodes a video signal and an audio signal from the selected and extracted signal of the broadcast channel, supplies the video signal to a video signal processor 14, and supplies the audio signal to an audio signal processor 15.

The video signal processor 14 performs a predetermined process on the video signal under the control of the control unit 10 and supplies the processed video signal to a display unit 17 including, for example, an LCD (Liquid Crystal Display) via a display controller 16. Accordingly, an image of a broadcast program of the selected broadcast channel is displayed on the display unit 17.

The audio signal processor 15 performs a predetermined process on the audio signal under the control of the control unit 10. In this embodiment, the audio signal processor 15 generates two left and right channel input audio signals SiL and SiR from the audio signal from the tuner unit 13 and supplies the processed audio signals SiL and SiR to a sound volume corrector 18.

The sound volume corrector 18 is a unit to which the sound volume correcting device according to this embodiment is applied. The input audio signals SiL and SiR are corrected in sound volume as described later and are output as output audio signals SoL and SoR. The output audio signals SoL and SoR from the sound volume corrector 18 are supplied to speakers 19L and 19R and are reproduced as sounds. Accordingly, the sounds of the broadcast program of the selected broadcast channel are output form the speakers 19L and 19R.

The sound volume correcting device according to this embodiment will be described now as the sound volume corrector 18.

### Sound Volume Correcting Device According to First Embodiment

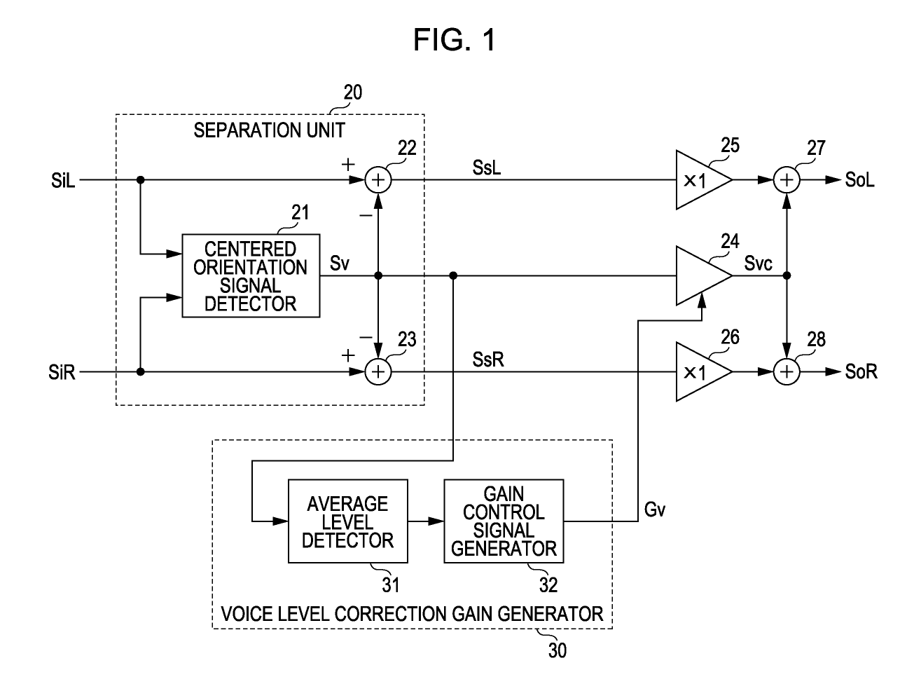

FIG. 1 is a block diagram illustrating the entire configuration of the sound volume corrector 18 as the sound volume correcting device according to a first embodiment of the invention.

In the first embodiment, the input audio signals are two left and right channel input audio signals. A main first component signal is a signal (hereinafter, referred to as “main voice signal”) containing a voice component as a main component out of the two left and right channel input audio signals. The other audio component other than the first component is a so-called live sound other than the main voice signal of the two left and right channel input audio signals. The signal containing the live sound component as a main component is hereinafter referred to as “main live sound signal”.

As shown in FIG. 1, in the first embodiment, the two left and right channel input audio signals SiL and SiR are supplied to a separation unit 20 separating the main voice signal and the main live sound signal. The separation unit 20 in this example includes a centered orientation signal detector 21 and two subtractors 22 and 23.

The centered orientation signal detector 21 is supplied with the two left and right channel input audio signals SiL and SiR and detects a main voice signal Sv as a centered orientation signal oriented at the center between the left and right channels. The main voice signal Sv detected by the centered orientation signal detector 21 is supplied to the subtractors 22 and 23.

The subtractor 22 subtracts the main voice signal Sv from the left channel audio signal SiL to acquire the left channel main live sound signal SsL. The subtractor 23 subtracts the main voice signal Sv from the right channel audio signal SiR to acquire the right channel main live sound signal SsR.

In this way, the separation unit 20 separates the main voice signal Sv and the left and right channel main live sound signals Ss1 and SsR from the two channel input audio signals SiL and SiR.

The main voice signal Sv from the separation unit 20 is supplied to adders 27 and 28 via a variable gain amplifier 24 as an example of the first component gain control means and is also supplied to a voice level correction gain generator 30.

In this example, the voice level correction gain generator 30 includes an average level detector 31 and a gain control signal generator 32. The average level detector 31 detects the average level of the main voice signal Sv and supplies the detected average level to a gain control signal generator 32.

The gain control signal generator 32 generates a gain control signal (voice level correction gain value) Gv for allowing the average level of the main voice signal Sv to be a predetermined reference level. The gain control signal generator 32 supplies the generated gain control signal Gv to the variable gain amplifier 24.

Therefore, in the variable gain amplifier 24, the gain is controlled so that the average level of the main voice signal is a constant level (reference level) even when the level of the main voice signal Sv greatly varies due to the gain control signal Gv. In this way, the output level of the corrected main voice signal Svc output from the variable gain amplifier 24 is automatically adjusted to the constant level. The corrected main voice signal Svc adjusted to the constant level is supplied to the adders 27 and 28.

On the other hand, the left channel main live sound signal SsL from the subtractor 22 is supplied to the adder 27 via the amplifier 25 of which the gain is “1” with an unchanged level. The right channel main live sound signal SsR from the subtractor 23 is supplied to the adder 28 via the amplifier 26 of which the gain is “1” with an unchanged level.

The adder 27 adds the left channel main live sound signal SsL to the corrected main voice signal Svc and outputs the volume-corrected left channel output audio signal SoL as the added output.

The adder 28 adds the right channel main live sound signal SsR to the corrected main voice signal Svc and outputs the volume-corrected right channel output audio signal SoR as the added output.

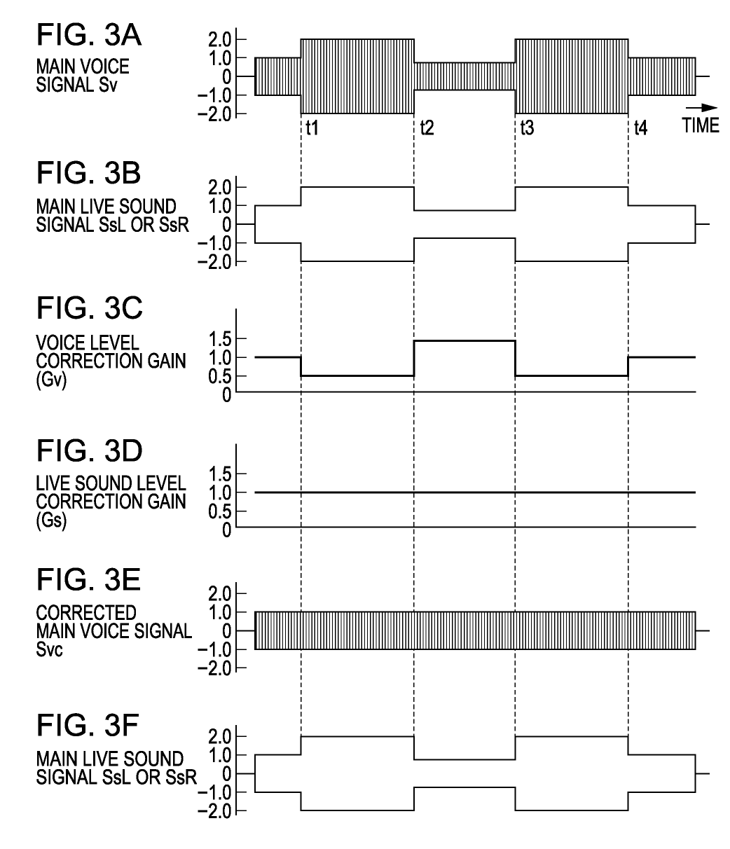

For example, it is assumed that the main voice signal Sv from the centered orientation signal detector 21 and the main live sound signal SsL or SsR have the level variations shown in FIGS. 3A and 3B.

In this case, the voice level correction gain in the variable gain amplifier 24 based on the gain control signal Gv from the voice level correction gain generator 30 is shown in FIG. 3C. Accordingly, the corrected main voice signal Svc from the variable gain amplifier 24 becomes a signal of a constant level shown in FIG. 3E.

On the other hand, in this example, since the main live sound signals SsL and SsR are maintained in the unchanged levels by the amplifiers 25 and 26 with the fixed gain of “1” shown in FIG. 3D, as shown in FIG. 3F, the output signals of the amplifiers 25 and 26 have the same level variations as shown in FIG. 3B.

In this way, the main voice signal Svc supplied as an input to the adders 27 and 28 is corrected in gain in a first gain control way such that the output level is kept constant. Accordingly, as described in the “SUMMARY OF THE INVENTION”, when the input audio signals SiL and SiR greatly vary in level, the sound volume level may wobble at the level varying point.

On the other hand, the left channel main live sound signal SsL and the right channel main live sound signal SsR supplied as the other input to the adders 27 and 28 are maintained at the unchanged levels in a second gain control way with the fixed gain of “1” in this example. Therefore, the original level variation of the input audio signal is maintained but the wobble in sound volume level due to the gain control in the first gain control way does not occur.

Therefore, in the left and right channel output audio signals SoL and SoR from the adders 27 and 28, the wobble in sound volume level of the corrected main voice signal Svc is masked by the left channel main live sound signal SsL and the right channel main live sound signal SsR. Accordingly, the wobble in sound volume level of the main voice signal Svc is not marked, thereby reducing the unpleasant feeling given to listeners.

According to this embodiment, by rapidly shifting the main voice signal to a proper level, it is possible to maintain the constant feeling of the voice level, thereby making it easy to hear voices such as speech. In the first embodiment, since the original level of the main live sound signal is not shifted with the gain of “1” and thus the realistic feeling is kept constant, the unpleasant feeling due to the level shift is reduced, thereby realizing a natural level shift.

The first embodiment is effective particularly when the variation in level of the main voice signal is small.

In this example, since the audio signal is reproduced by two left and right channel speakers, the adders 27 and 28 are provided. However, when a center channel speaker is provided in addition to the two left and right channel speakers, the corrected main voice signal may be supplied to the center channel speaker and the output audio signals of the amplifiers 25 and 26 may be supplied to the two left and right channel speakers. In this case, since the output sound of the center channel speaker and the output sounds of the two left and right channel speakers are acoustically combined, the wobble in sound volume level due to the gain control in the first gain control way is masked and is thus not marked.

### Configuration of Centered Orientation Signal Detector

### First Example

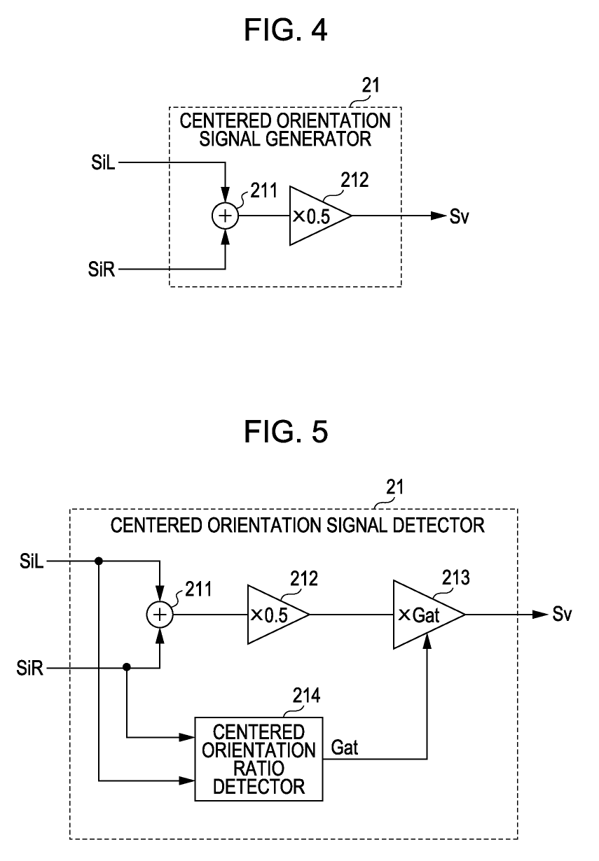

FIG. 4 is a diagram illustrating a first configuration example of the centered orientation signal detector 21 of this example. In this example, the centered orientation signal detector 21 includes an adder 211 and an amplifier 212 with a fixed gain of “0.5”.

In the centered orientation signal detector 21, the left and right channel input audio signals SiL and SiR are added by the adders 211 and the added output signal is output from the amplifier 212. The output signal of the amplifier 212 is the main voice signal Sv.

In the first example, the average value of the main voice signal Sv is equal to the average value of the added signal of the left and right input audio signals SiL and SiR. The voice level correction gain generator 30 generates the gain control signal Gv so that the average level of the main voice signal Sv is a constant level. Therefore, in the first example, the voice level correction gain generator 30 generates the gain control signal Gv so that the added signal of the left and right channel input audio signals SiL and SiR, that is, the total level of the input audio signals, is the constant level.

### Second Example

FIG. 5 is a second configuration example of the centered orientation signal detector 21. In the second example, the output of the first example is not output with the unchanged level, but a signal having a component more oriented to the center than the output of the first example is obtained.

In this example, the centered orientation signal detector 21 includes a gain-adjusted amplifier 213 and a centered orientation ratio detector 214, in addition to the adder 211 and the amplifier 212 with the fixed gain of “0.5” in the first example.

In the centered orientation signal detector 21 of this example, the output signal of the amplifier 212 is supplied to the gain-adjusted amplifier 213 and the output signal of the gain-adjusted amplifier 213 is the main voice signal Sv.

In the centered orientation signal detector 21 of this example, the left and right channel input audio signals SiL and SiR are also supplied to the centered orientation ratio detector 214. The centered orientation ratio detector 214 generates a gain control signal Gat for controlling the gain of the gain-adjusted amplifier 213 depending on the ratio of the signal oriented on the center to the entire input audio signals.

Since the gain of the gain-adjusted amplifier 213 is controlled by the gain control signal Gat from the centered orientation ratio detector 214, the main voice signal Sv contains the signal component corresponding to the ratio oriented on the center out of the output of the amplifiers 212. That is, the main voice signal Sv in the second example is a signal containing the signal component more oriented on the center than that of the first example.

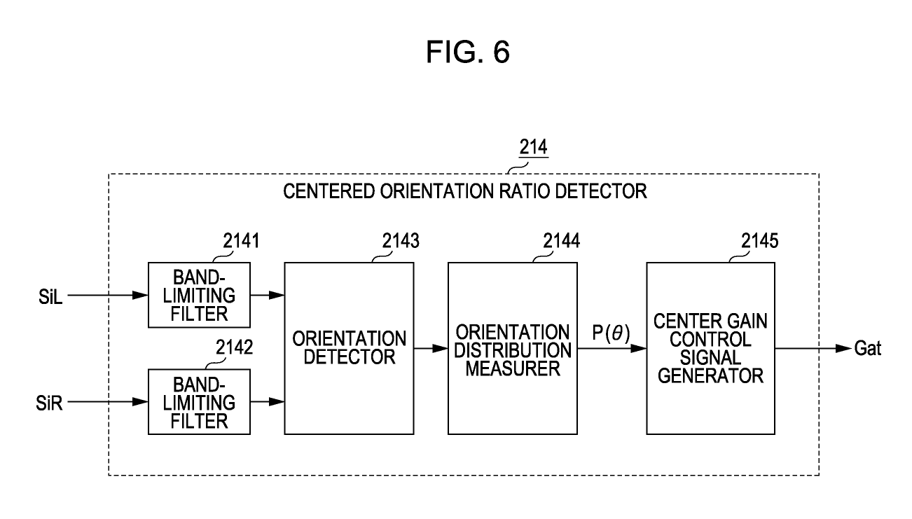

The centered orientation ratio detector 214 may have the configuration shown in FIG. 6.

That is, the centered orientation ratio detector 214 includes band-limiting filters 2141 and 2142, an orientation detector 2143, an orientation distribution measurer 2144, and a center gain control signal generator 2145.

For example, the components in the frequency bands such as low-band components hardly giving an orientation feeling are removed from the two left and right channel input audio signals SiL and SiR input to the centered orientation ratio detector 214 by the band-limiting filters 2141 and 2142.

The two channel input audio signals SiL and SiR of which the band is limited by the band-limiting filters 2141 and 2142 are supplied to the orientation detector 2143. The orientation detector 2143 detects the orientations of the two channel input audio signals SiL and SiR at the time of detecting the orientation for each predetermined period on the basis of the levels of the two channel input audio signals SiL and SiR of which the band is limited.

That is, the orientation detector 2143 samples the levels (amplitudes) of the two channel input audio signals SiL and SiR of which the band is limited to each predetermined sampling period. In this example, the orientation detector 2143 detects the orientation at the latest sampling time as the orientation at the present time.

In this case, the orientation detector 2143 detects the orientation at the latest sampling time using the levels of the input audio signals SiL and SiR at the latest sampling time and at a sampling time prior thereto.

When the two channel input audio signals SiL and SiR are digital audio signals, the sampling period can be set to be equal to the sampling period of the digital audio signals. The sampling period may not be equal to one sampling period of the digital audio signal, but may be set to be equal to plural sampling periods. When the input audio signals of the orientation detector 2143 are analog signals, the analog signal may be converted into a digital audio signal at an input stage of the orientation detector 2143.

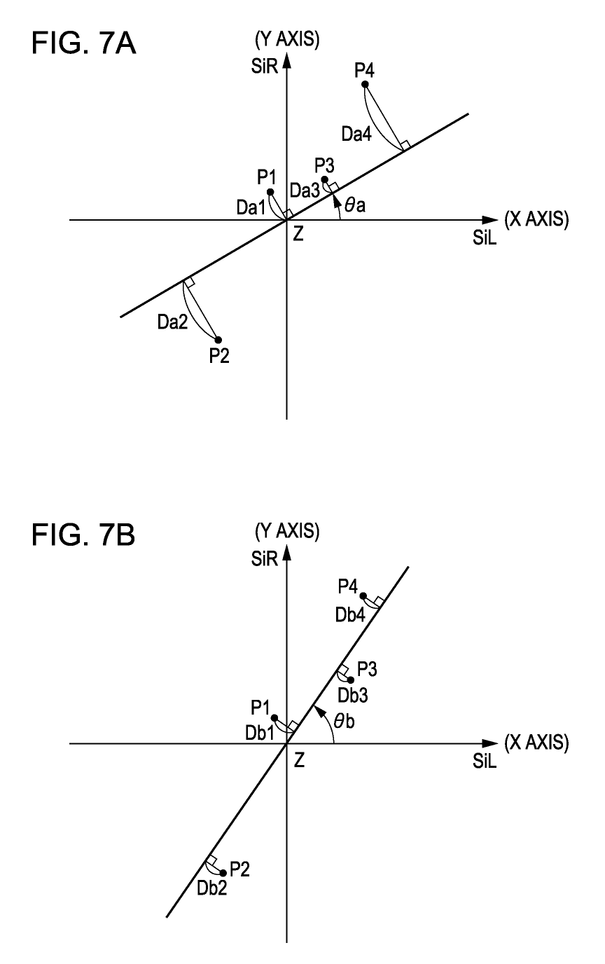

The method of detecting an orientation in the orientation detector 2143 will be described now with reference to FIGS. 7A and 7B. FIGS. 7A and 7B show a coordinate space where the X axis represents the amplitude of the left channel audio signal SiL and the Y axis represents the amplitude of the right channel audio signal SiR.

The orientation detector 2143 acquires the levels of the two channel input audio signals SiL and SiR at the orientation detecting time in each sampling period and plots the coordinate points corresponding thereto in the coordinate space shown in FIGS. 7A and 7B, like P1, P2, P3, and P4. In this example, P4 is the coordinate point at the latest detecting time.

When a straight line (straight line passing through an intersection Z of the X axis and the Y axis) expressed by y=k·x (where k is a constant) is made to rotate about the intersection Z by ±90°, that is, when the constant k is changed, the orientation detector 2143 calculates with what constant k (with what slope angle) the plotted coordinate points P1, P2, P3, and P4 get closest to the straight line. That is, the orientation detector calculates the constant k of the straight line having the smallest total sum of the distances Da1, Da2, Da3, and Da4 or the distances Db1, Db2, Db3, and Db4 from the straight lines with different constants k to the coordinate points P1, P2, P3, and P4.

The orientation detector 2143 sets the slope angle corresponding to the calculated constant k of the straight line as the orientation at the present time to be detected. In the example of FIGS. 7A and 7B, the orientation is detected in a state where the X axis, that is, the angle of the orientation (left direction) of the left channel is 0° and the angle θ about the X axis (hereinafter, referred to as “orientation angle”) is the orientation angle.

In the example of the coordinate points P1, P2, P3, and P4 in FIG. 7A, the orientation angle is detected as θa. In the example of the coordinate points P1, P2, P3, and P4 of FIG. 7B, the orientation angle is detected as θb.

In this embodiment, the orientation detector 2143 does not use the same weight for the levels of the two channel input audio signals at the present time (at the latest sampling time) and the levels of the two channel input audio signals at the previous sampling time. In this embodiment, the orientation detector 2143 uses the greater weight for the levels of the two channel input audio signals at the sampling time closest to the present time.

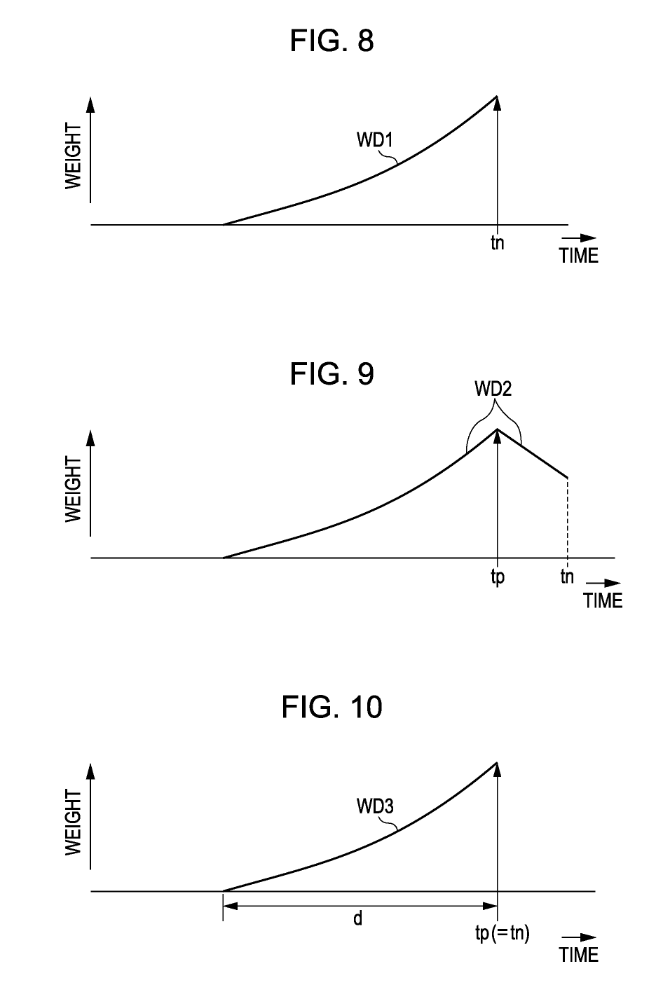

Accordingly, the orientation detector 2143 employs a time window WD1 having such an exponential curve characteristic that the weight for the sampling values of the levels of the two channel input audio signals becomes greater as it nears the present time (the latest sampling time to in this example) as shown in FIG. 8.

In the above description, the present time which is the time for the processing signal is set to the latest sampling time (latest sample time). However, a delay circuit for delay by a predetermined time τ may be provided to the input stage of the variable gain amplifier 24 and the amplifiers 25 and 26 and the present time as a processing time may be set to a time obtained by delaying the input audio signals SiL and SiR by the predetermined time τ.

In this case, the orientation detector 2143 can detect the orientation also using the two channel input audio signals SiL and SiR in the future from the present time as a processing time. For example, in the example shown in FIGS. 7A and 7B, the present time as the processing time may be set to P2 or P3.

In this case, a time window WD2 having an exponential curve characteristic shown in FIG. 9 is used instead of the time window WD1. The time window WD2 has such an exponential curve characteristic that the weight at the present time tp as the processing time is the greatest and the weight becomes smaller as it departs further from the present time tp, that is, as it departs to the past and the future.

The levels of the two channel input audio signals at the present time can be used without any change, without weighting the levels of the two channel input audio signals SiL and SiR at the past and/or future sampling time.

In this way, the orientation detector 2143 can detect the orientation angle θ indicating the orientation of the two channel input audio signals SiL and SiR at the present time.

However, the detected orientation angle θ at the present time serves to define the orientation of the input audio signals at a time in one direction and does not reflect the intensity of signal in the corresponding direction. Therefore, in this embodiment, the detection result (orientation angle θ) of the orientation of the two channel input audio signals SiL and SiR at the present time detected by the orientation detector 2143 is supplied to the orientation distribution measurer 2144 in consideration of this point.

The orientation distribution measurer 2144 calculates a distribution of the orientation angle θ in all the orientations detected by the orientation detector 2143 over a predetermined time interval d, and measures what ratio the orientations of the two channel input audio signals have in the corresponding direction.

In this case, the predetermined time interval d is selected, for example, as several milli-seconds to several hundreds milli-seconds and several tens of milli-seconds in this example. In this embodiment, the orientation distribution measurer 2144 weights the orientation angle θ detected at the predetermined time interval d by the orientation detector 2143 in the same way as the weighting coefficient characteristic of the orientation detector 2143.

That is, the orientation distribution measurer 2144 performs the weighting operation using a time window WD3 (see FIG. 10) where the weight exponentially increases as it nears the present time tp (tp=tn (the latest sampling time) in this example).

As described above, the time delay τ is prepared for the input audio signals and the time window of the orientation distribution measurer 2144 is the same as shown in FIG. 9 when the time window for weighting in the orientation detector 2143 is set to the same as shown in FIG. 9. In this case, the time interval d is a time interval including both the future and the past from the present time tp. The orientations may be used with non-weighted values.

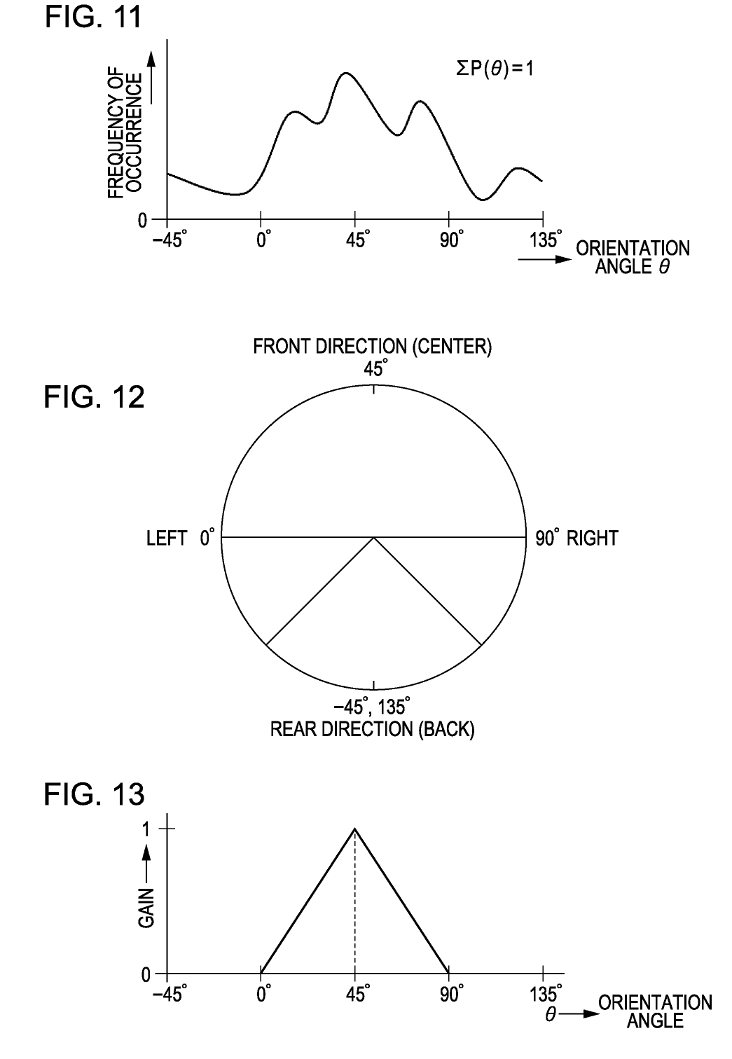

FIG. 11 is a diagram illustrating an example of an orientation distribution P(θ) which is the distribution of the orientation angle θ calculated by the orientation distribution measurer 2144, where the horizontal axis represents the orientation angle θ about the X axis (the left channel orientation) and the vertical axis represents the frequency of occurrence (<1) of each orientation angle. In this embodiment, when the total sum of the orientation distribution P(θ) is calculated at all the orientation angles θ, the distribution is generated so that the total sum is 1, that is, ΣP(θ)=1.

The relation of the orientation angle θ and the orientation of the audio signals is shown in FIG. 12. The front, the left, and the right shown in FIG. 12 are direction names based on a listener.

In this way, the information on the orientation distribution P(θ) shown in FIG. 11 is obtained at the present time (present sampling time or present sample time: processing time) from the orientation distribution measurer 2144.

The information on the orientation distribution P(θ) is supplied to the center gain control signal generator 2145. The center gain control signal generator 2145 generates a center gain control signal on the basis of the orientation distribution P(θ) calculated by the orientation distribution measurer 2144 so that a gain is greater as a signal is more oriented to the center and the gain is smaller otherwise.

The center gain control signal generator 2145 includes a gain table memory not shown. The gain table memory previously stores gain table information K(θ) for generating the gain control signal supplied to the gain-adjusted amplifier 213.

The gain table information K(θ) has a gain characteristic in which all the orientation angles (−45° to 135°) are weighted in the center orientation. FIG. 13 shows an example of the gain table information K(θ).

That is, in the gain table information K(θ) of this example, as shown in FIG. 13, the gain is the maximum “1” in the front direction (center direction: θ=45°). In the orientation angle range (0° to)45°) inclined to the left from the center direction and the orientation angle range (45° to 90°) inclined to the right from the center direction, the gain characteristic is set so that the gain is smaller as it goes apart from the center direction.

The center gain control signal generator 2145 calculates the total sum of multiplications of the gain values of the gain table information K(θ) by the information on the orientation distribution P(θ) calculated by the orientation distribution measurer 2144 at all the orientation angles.

That is, the center gain control signal generator 2145 generates the gain control signal Gat by Gat=Σ(K(θ)×P(θ)).

The gain control signal Gat generated by the center gain control signal generator 2145 in this way is supplied as the output of the centered orientation ratio detector 214 to the gain-adjusted amplifier 213.

Therefore, the main voice signal Sv including the signal component further oriented to the center than that in the first example is obtained from the gain-adjusted amplifier 213.

The centered orientation signal detector 21 is not limited to the first example and the second example described above.

### Sound Volume Correcting Device According to Second Embodiment

The above-mentioned first embodiment employs the gain control way that the sound volume of the main live sound signal is not corrected. However, for example, when the level variation of the input audio signal due to the switching of channel is great, it may be preferable that the gain of the main live sound signal is controlled along with the main voice signal. A second embodiment of the invention can cope with this case.

In the second embodiment described below, the sound volume correcting device is applied to the sound volume corrector 18 of the television broadcast receiver shown in FIG. 2, similarly to the first embodiment.

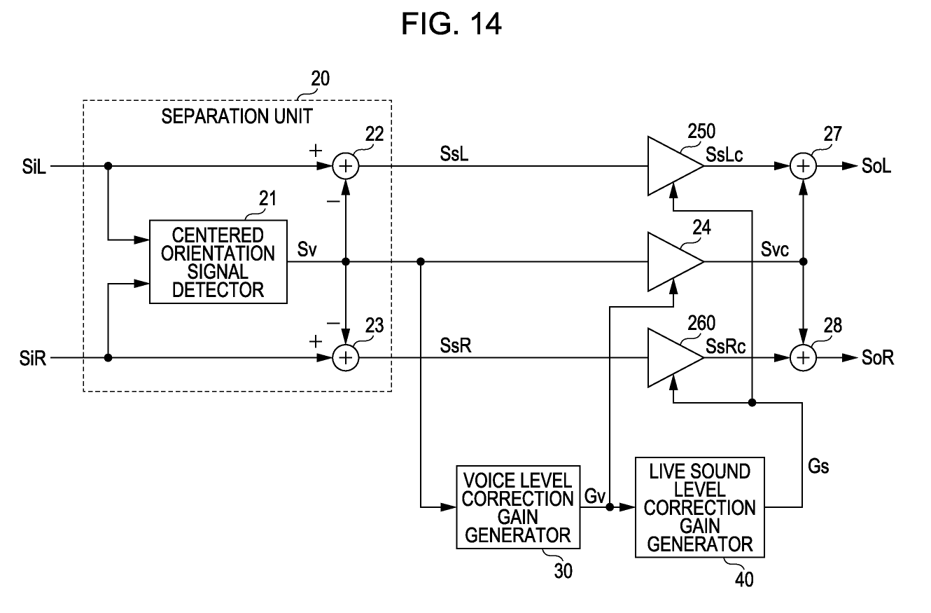

FIG. 14 is a block diagram illustrating the entire configuration of the sound volume corrector 18 according to the second embodiment. In FIG. 14, the same elements as the sound volume corrector 18 according to the first embodiment shown in FIG. 1 are referenced by the same reference numerals and signs.

In the second embodiment, variable gain amplifiers 250 and 260 are prepared for the left and right channel main live sound signals SsL and SsR from the adders 22 and 23, instead of the amplifiers 25 and 26 with a fixed gain in the first embodiment.

In the second embodiment, a live sound level correction gain generator 40 generating a gain control signal Gs (live sound level correction gain value) of the main live sound signals SsL and SsR is provided, in addition to the voice level correction gain generator 30 in the first embodiment.

The gain control signal Gs from the live sound level correction gain generator 40 is supplied to the variable gain amplifiers 250 and 260 so as to control the gains of the left and right main live sound signals SsL and SsR in a gain control way different from that of the main voice signal Sv.

The live sound level correction gain generator 40 receives the gain control signal Gv from the voice level correction gain generator 30, performs a process based on the gain control signal Gv, and generates the gain control signal Gs for correcting the gain of the main live sound signal.

Since a certain process is additionally performed on the gain control signal Gv, the gain control way for the main voice signal Sv using the gain control signal Gv is different from the gain control way for the main live sound signals SsL and SsR using the gain control signal Gs.

However, in this case, the gain control way for the main live sound signals SsL and SsR using the gain control signal Gs does not immediately follow the great level variation of the input audio signal. That is, in the second embodiment, similarly to the first embodiment, the gain control way for the main voice signal Sv intermediately follows the level variation of the input audio signal and keeps the output level constant. However, the gain control way for the main live sound signals SsL and SsR has a characteristic that it does not immediately follow the great level variation of the input audio signal, unlike the above-mentioned gain control way.

The configuration for processing the main voice signal Sv in the second embodiment is the same as the first embodiment. Therefore, the gain of the main voice signal Svc supplied as an input to the adders 27 and 28 is corrected in the first gain control way that the output level is kept constant. Accordingly, as described in the “SUMMARY OF THE INVENTION”, when the input audio signals SiL and SiR greatly vary in level, an wobble in sound volume level may occur at the level varying point.

On the other hand, in the second embodiment, the gains of the left and right channel main live sound signals SsL and SsR are controlled in a second gain control way different from the first gain control way by the variable gain amplifiers 250 and 260 and the resultant signals are supplied to the adders 27 and 28. In this embodiment, the gain control way for the main live sound signals SsL and SsR has a characteristic such that it does not immediately follow the great level variation of the input audio signal.

Therefore, the wobble in the sound volume level at the level greatly-varying point in the main voice signal due to the gain control of the first gain control way does not occur in the main live sound signals.

Accordingly, in the left and right channel output audio signals SoL and SoR from the adders 27 and 28, the wobble in the sound volume level of the corrected main voice signal Svc is masked by the left channel and right channel main live sound signals SsL and SsR. As a result, the wobble in sound volume level of the main voice signal Svc is not marked, thereby reducing the unpleasant feeling given to a listener.

### Configuration of Live Sound Level Correction Gain Generator

### First Example

When the level variation of the input audio signal or the level variation of the main voice signal Sv is great and only the output level of the main voice signal Sv is controlled in gain to a constant level, the balance for the original input audio signal may deteriorate, thereby giving the unpleasant feeling.

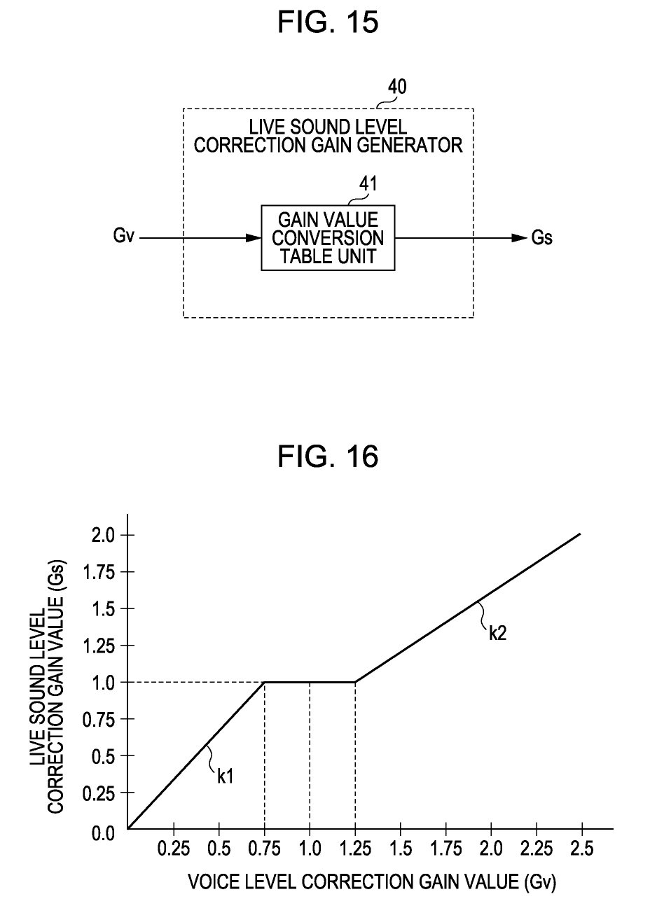

The first example is to improve the above-mentioned problem. FIG. 15 is a diagram illustrating the configuration of the live sound level correction gain generator 40 in the first example. In the first example, the live sound level correction gain generator 40 includes a gain value switching table unit 41.

The gain value switching table unit 41 serves to receive the gain control signal Gv of the main voice signal Sv as an input signal and to output the gain control signal Gs of the main live sound signals SsL and SsR, and includes a gain value switching table memory (not shown).

FIG. 16 is a diagram illustrating an example of gain value switching table information stored in the gain value switching table memory of the gain value switching table unit 41.

When the level variation of the main voice signal Sv is small or when the level variation of the entire input audio signals (using the centered orientation signal detector 21 of the fist example) is small, the voice level correction gain value based on the gain control signal Gv does not vary greatly about Gv=1.

In this case, the balance of the main live sound signal and the main voice signal is not deviated greatly from the original input audio signal, and the unpleasant feeling is not given. Accordingly, in a small level variation range, the main live sound signals SsL and SsR may be output from the amplifier with the fixed gain of “1”, similarly to the first embodiment.

Therefore, in the example shown in FIG. 16, the gain control signal Gs for the main live sound signals is set to the gain value of Gs=1 in the range of 0.75≦Gv≦1.25.

In this example, when the level variation of the input audio signal or the level variation of the main voice signal Sv is deviated from the small level variation range, the gain of the main live sound signals SsL and SsR is controlled by following the level variation with a predetermined ratio to the gain control signal Gv.

That is, in the example shown in FIG. 16, in the range of Gv<0.75 where the input level is great, the gain control signal Gs for the main live sound signals SsL and SsR is output on the basis of the gain control signal Gv with the relation of Gs/Gv=k1 (=1/0.75).

In the range of Gv>1.25 where the input level is small, the gain control signal Gs for the main live sound signals SsL and SsR is output on the basis of the gain control signal Gv with the relation of Gs/Gv=k2 (=2/2.5).

Accordingly, even when the voice level correction gain greatly varies, the live sound level correction gain follows the voice level correction gain with a constant ratio. As a result, it is possible to prevent the balance of the main live sound signal level relative to the main voice signal level from being greatly deteriorated. Therefore, it is possible to realize the natural level shift even when the variation in level is great.

The gain value switching table unit 41 can read the gain control signal Gs for the corresponding main live sound signals and output the read gain control signal, using the value of the gain control signal Gv for the main voice signal Sv as a reading address input of the gain value switching table memory.

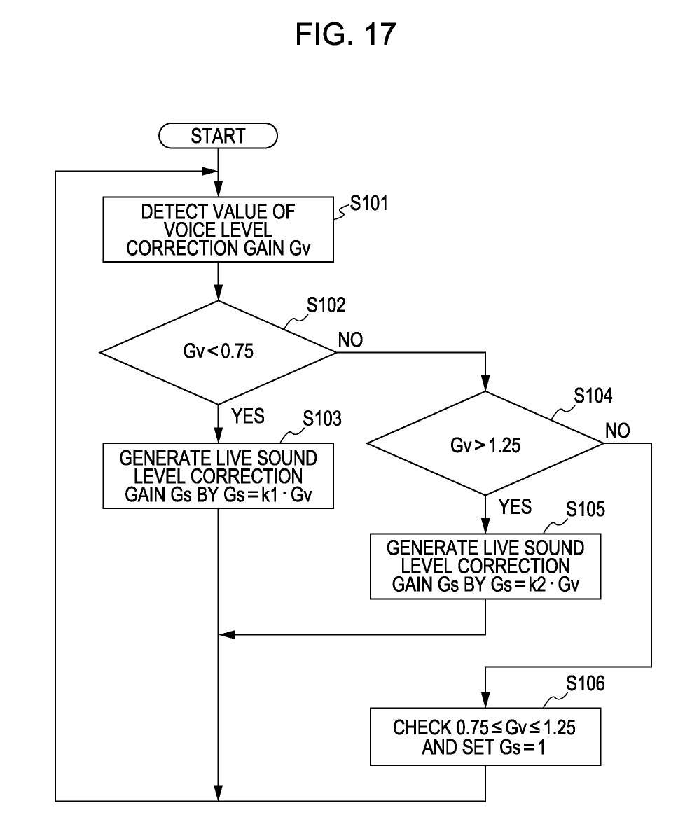

The gain value switching table unit 41 may be constructed by functional means using software operations. FIG. 17 shows an example of a flowchart of the software operations in this case.

The gain value switching table unit 41 senses the gain value of the gain control signal Gv for the input main voice signal (step S101). Then, it is determined whether the gain value Gv satisfies Gv<0.75 (step S102). When it is determined that Gv<0.75 is satisfied, the gain control signal Gs for the main live sound signals SsL and SsR is calculated by an operation of Gs=k1×Gv (step S103).

When it is determined in step S102 that Gs<0.75 is not satisfied, it is determined whether Gv>1.25 is satisfied (step S104). When it is determined that Gv>1.25 is satisfied, the gain control signal Gs for the main live sound signals SsL and SsR is calculated by an operation of Gs=k2×Gv (step S105).

When it is determined in step S104 that Gv>1.25 is not satisfied, it is checked that 0.75≦Gv≦1.25 is satisfied and Gs=1 is set (step S106).

The above-mentioned processes from step S101 are repeated after steps S103, S104, and S106.

The numerical values of the gain described above are only examples, and the gain is not limited to the numerical values. In the small level variation range about Gv=1, that is, in the range of α≦Gv≦β, 1−α=β−1 is set in the example, but 1−α≠β−1 may be satisfied.

The value k1 of the ratio in the range of Gv<α and the value k2 of the ratio in the range of Gv>β are only examples, and k1=k2 may be set.

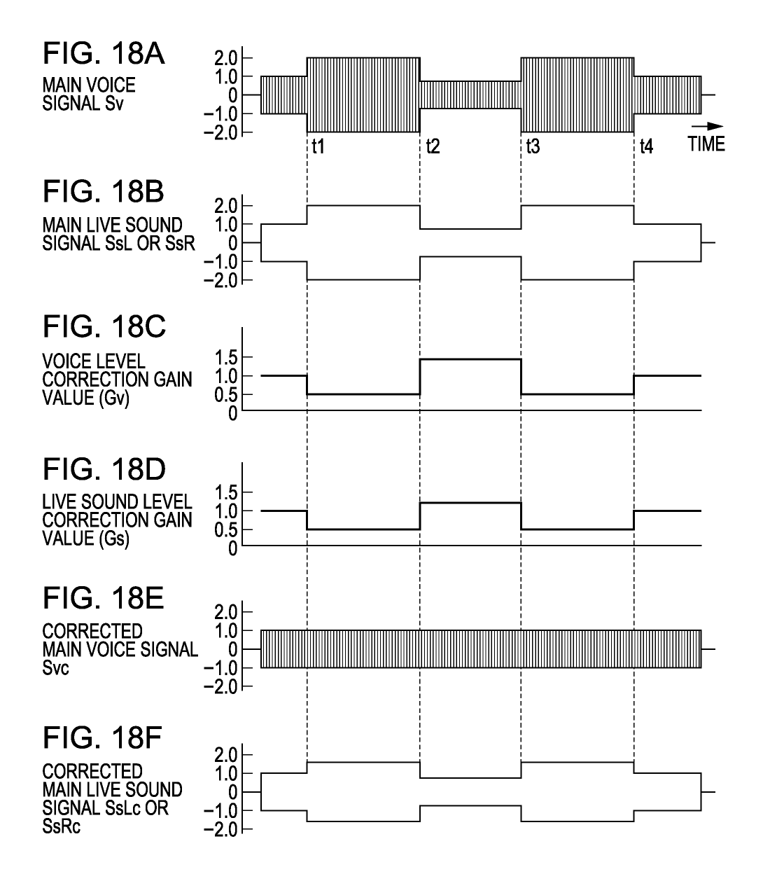

The sound volume correcting process in the first example will be described with reference to the timing chart of signal waveforms shown in FIGS. 18A to 18F.

FIGS. 18A to 18F are similar to FIGS. 3A to 3F used to describe the first embodiment. That is, when the main voice signal Sv and the main live sound signal SsL or SsR have the level variation shown in FIGS. 18A and 18B, the voice level correction gain for the main voice signal Sv based on the gain control signal Gv is the same as shown in FIG. 18C.

The gain of the variable gain amplifier 24 is controlled by the gain control signal Gv. As a result, the corrected main voice signal Svc from the variable gain amplifier 24 is a signal with the same constant level as shown in FIG. 18E.

In this example, the gain control signal Gs for the main live sound signal SsL and SsR is generated as described above on the basis of the gain control signal Gv to be the same as shown in FIG. 18D.

The gains of the variable gain amplifiers 250 and 260 are controlled by the gain control signal Gs. As a result, the corrected main live sound signals SsLc and SsRc from the variable gain amplifier 250 and 260 are the same as shown in FIG. 18F, which are obtained by controlling the gain of the main live sound signals SsL and SsR shown in FIG. 18B.

As can be clearly seen from the above description, the first example is effective when the level variation of the input audio signal or the main voice signal is great, and the first embodiment can be applicable when the level variation of the input audio signal or the main voice signal Sv is small.

Therefore, a configuration may be considered for detecting the level variation of the input audio signal and automatically switching the gain control way for the main live sound signal depending on the detection result.

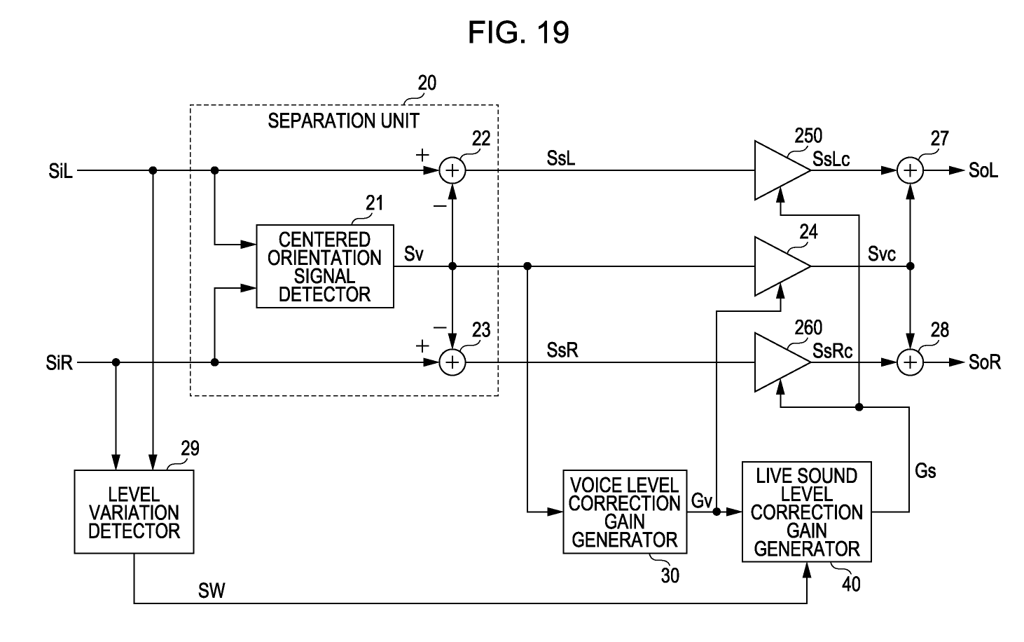

FIG. 19 shows the configuration of this case. As shown in FIG. 19, a level variation detector 29 detecting the entire level variation of two left and right input audio signals SiL and SiR is provided.

The live sound level correction gain generator 40 of this example has a way where the variable gain amplifiers 250 and 260 have the fixed gain “1” for the main live sound signal similarly to the first embodiment and a way where the gain is controlled similarly to the second embodiment.

The level variation detector 29 adds the two left and right channel input audio signals SiL and SiR, detects the level variation of the added signal, and supplies a switching control signal SW to the live sound level correction gain generator 40 depending on the detection result.

When the detected level variation is inside a predetermined small level range, the level variation detector 29 supplies the live sound level correction gain generator 40 with the switching control signal SW indicating the way where the gain values of the variable gain amplifiers 250 and 260 are set to the fixed gain “1”.

When the detected level variation is outside the small level range, the level variation detector 29 supplies the live sound level correction gain generator 40 with the switching control signal SW indicating the way where the gain control signal Gs is supplied to the variable gain amplifiers 250 and 260.

Accordingly, in the example shown in FIG. 19, when the level variation of the input audio signal is great, the way of the second embodiment is automatically set, thereby avoiding the problem of the first embodiment.

### Second Example

In a second example, the main live sound signals SsL and SsR are not controlled with the fixed gain similar to the first embodiment or the first example, but is controlled under the gain control of the main voice signal Sv. Accordingly, the entire balance is set to the balance of the original input audio signal, thereby reproducing natural sounds.

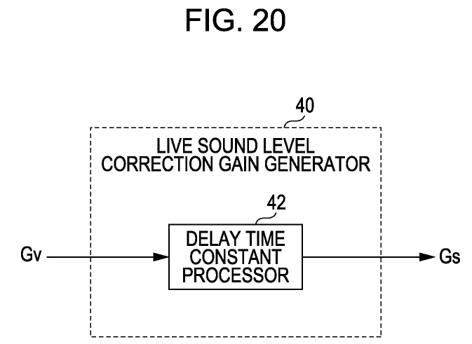

FIG. 20 is a diagram illustrating the configuration f the live sound level correction gain generator 40 in the second example. In the second example, the live sound level correction gain generator 40 includes a delay time constant processor 42.

That is, in the second example, the delay time constant processor 42 performs a delay time constant process on the gain control signal Gv for the main voice signal Sv and generates the gain control signal Gs for the main live sound signals SsL and SsR. That is, the live sound level correction gain having a time delay characteristic following the voice level correction gain late can be obtained.

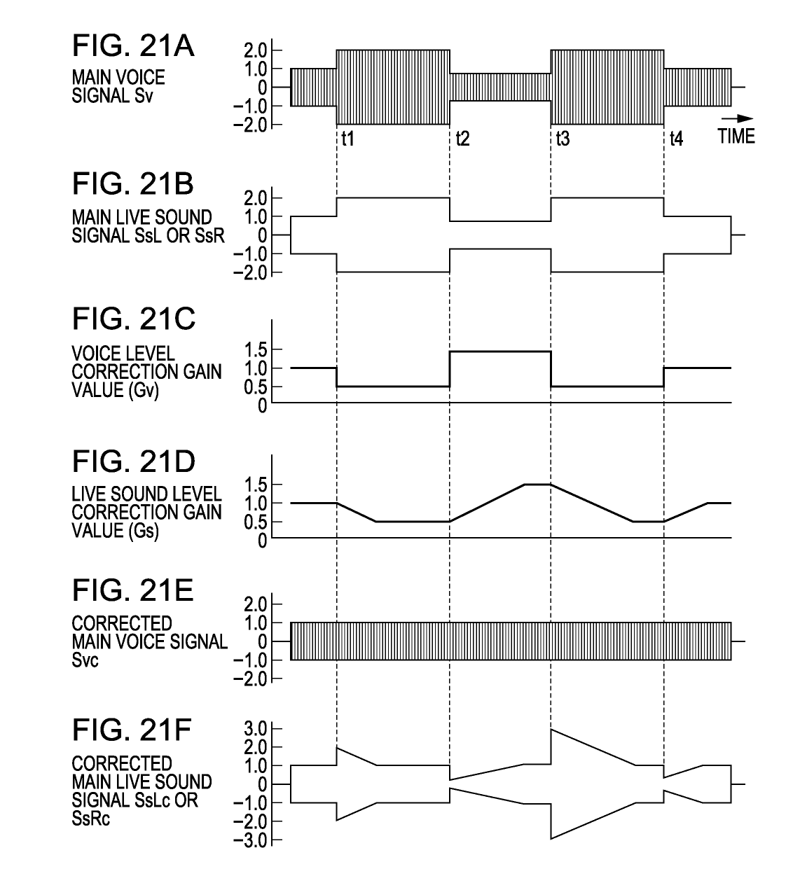

The sound volume correcting process in the second example will be described with reference to the timing chart of signal waveforms shown in FIGS. 21A to 21F.

FIGS. 21A to 21F are similar to FIGS. 18A to 18F used to describe the first example. That is, when the main voice signal Sv and the main live sound signal SsL or SsR have the level variation shown in FIGS. 21A and 21B, the voice level correction gain for the main voice signal Sv based on the gain control signal Gv is the same as shown in FIG. 21C.

The gain of the variable gain amplifier 24 is controlled by the gain control signal Gv. As a result, the corrected main voice signal Svc from the variable gain amplifier 24 is a signal with the same constant level as shown in FIG. 21E.

On the other hand, in the second example, the gain control signal Gv shown in FIG. 21C is subjected to the delay time constant process and thus the gain control signal Gs for the main live sound signals SsL and SsR varies with the time delay characteristic where the gain value has a predetermined time constant as shown in FIG. 21D.

The gains of the variable gain amplifiers 250 and 260 are controlled by the gain control signal Gs. As a result, the corrected main live sound signals SsLc and SsRc from the variable gain amplifier 250 and 260 are the same as shown in FIG. 21F.

According to the second example, at the instant when the main voice signal Sv is rapidly shifted to a proper level, the live sound level correction gain is not made to vary and the live feeling is kept constant. Since the main live sound signals SsL and SsR are slowly corrected in level with delay, the unpleasant feeling due to the great level variation at the level varying point can be reduced by the gain control. Accordingly, it is possible to realize the natural level shift. Since the balance of the main voice signal Sv and the main live sound signal SsL and SsR is converged to the balance of the original input audio signal, it is possible to realize a more natural automatic sound volume correction.

### Third Example

In the second example, the main live sound signals SsL and SsR are controlled in gain to correspond to the gain control of the main voice signal Sv. Therefore, when the correction gain for the main voice signal Sv becomes very great or very small, the correction gain for the main live sound signals SsL and SsR follows it.

A third example is a modified example of the second example and is designed to improve the above-mentioned problem.

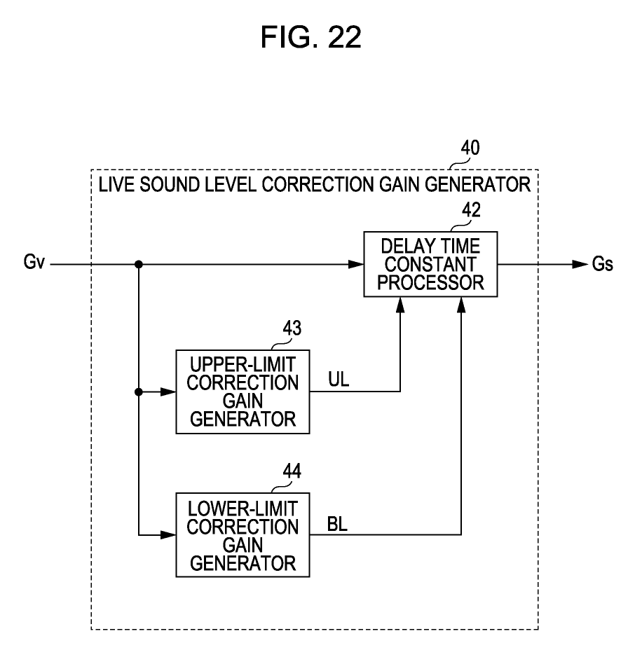

FIG. 22 shows the configuration of the live sound level correction gain generator 40 according to the third example and includes an upper-limit correction gain generator 43 and a lower-limit correction gain generator 44, in addition to the delay time constant processor 42.

The upper-limit correction gain generator 43 receives the gain control signal Gv for the main voice signal Sv as an input signal and generates an upper-limit correction gain UL by multiplying the received gain control signal Gv by a predetermined reference value Ku (Ku>1). In this example, the reference value Ku is set to Ku=2. The upper-limit correction gain generator 43 supplies the generated upper-limit correction gain UL to the delay time constant processor 42.

The lower-limit correction gain generator 44 receives the gain control signal Gv for the main voice signal Sv as an input signal and generates a lower-limit correction gain BL by multiplying the received gain control signal Gv by a predetermined reference value Kb (Kb<1). In this example, the reference value Kb is set to Kb=0.5. The lower-limit correction gain generator 44 supplies the generated lower-limit correction gain BL to the delay time constant processor 42.

The delay time constant processor 42 in the third example performs the delay time constant process on the gain control signal Gv for the main voice signal Sv input thereto and acquires the gain control signal Gs for the main live sound signals. However, in the third example, the delay time constant processor 42 monitors the upper-limit correction gain UL and the lower-limit correction gain BL and limits the gain control signal Gs to satisfy a conditional expression of upper-limit correction gain UL≧Gs≧lower-limit correction gain BL.

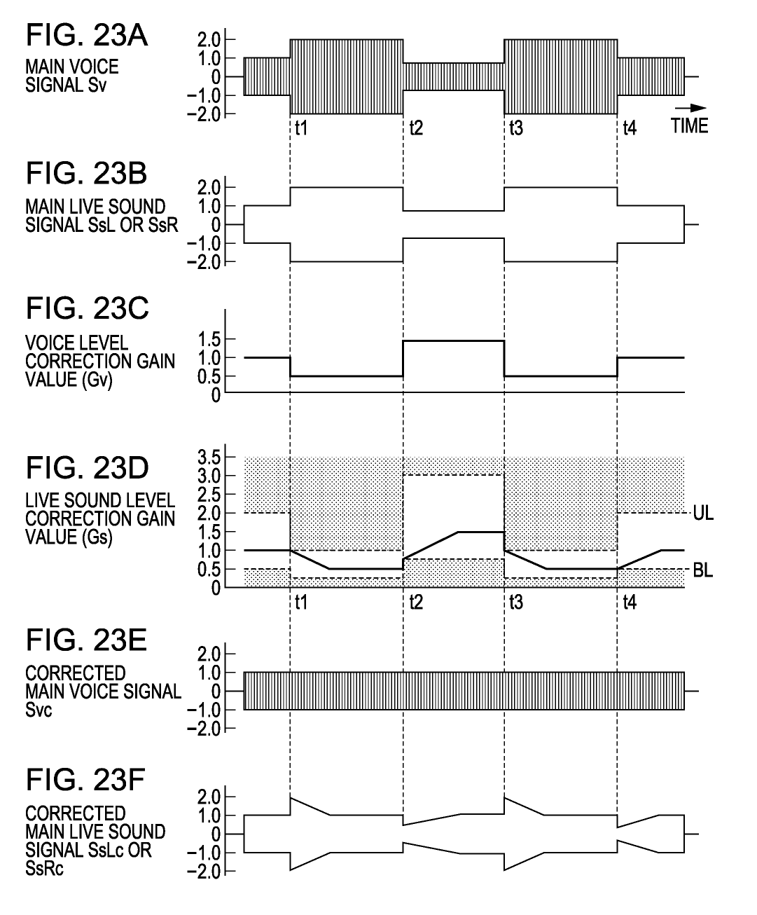

The sound volume correcting process in the third example will be described with reference to the timing chart of signal waveforms shown in FIGS. 23A to 23F.

FIGS. 23A to 23F are similar to FIGS. 21A to 21F used to describe the second example. That is, when the main voice signal Sv and the main live sound signal SsL or SsR have the level variation shown in FIGS. 23A and 23B, the voice level correction gain for the main voice signal Sv based on the gain control signal Gv is the same as shown in FIG. 23C.

The gain of the variable gain amplifier 24 is controlled by the gain control signal Gv. As a result, the corrected main voice signal Svc from the variable gain amplifier 24 is a signal with the same constant level as shown in FIG. 23E.

On the other hand, in the third example, the gain control signal Gv shown in FIG. 23C is subjected to the delay time constant process and thus the gain control signal Gs for the main live sound signals SsL and SsR varies with the time delay characteristic where the gain value has a predetermined time constant as shown in FIG. 23D. As shown in FIG. 23D, the gain control signal Gs in this case is limited to being not greater than the upper-limit correction gain UL and not smaller than the lower-limit correction gain BL.

That is, as shown in FIG. 23D, in the interval from time t1 to time t2, the gain control signal Gs satisfies the conditional expression of upper-limit correction gain UL≧Gs≧lower-limit correction gain BL, which is the same as the second example (FIG. 21D).

However, after time t2, the lower-limit correction gain value BL is greater than the value before time t2 and thus the gain value Gs is equal to or less than the lower-limit correction gain BL. Therefore, the delay time constant processor 42 sets the gain value Gs to the lower-limit correction gain BL at time t2 and starts the delay time constant process on the gain control signal Gv using the lower-limit correction gain BL as a start point.

In the example shown in FIGS. 23A to 23F, after time t3, the upper-limit correction gain UL is smaller than the value before time t3, and thus the gain value Gs is equal to or greater than the upper-limit correction gain UL. Therefore, the delay time constant processor 42 sets the gain value Gs to the upper-limit correction gain UL at time t3 and starts the delay time constant process on the gain control signal Gv using the upper-limit correction gain UL as a start point.

The gains of the variable gain amplifiers 250 and 260 are controlled by the gain control signal Gs. As a result, the corrected main live sound signals SsLc and SsRc from the variable gain amplifier 250 and 260 are the same as shown in FIG. 23F.

According to the third example, the level of the main live sound signal is not greatly deviated from the level of the main voice signal. Accordingly, when the variation in voice level is great, it is possible to realize the natural level shift. Since the balance of the main voice signal Sv and the main live sound signals SsL and SsR is converged to the original balance, it is possible to realize the more natural automatic sound volume correction.

Even when the correction gain for the main voice signal Sv becomes very great or very small, the correction gain Gs for the main live sound signals SsL and SsR is limited to a predetermined level range, which contributes to realizing the natural automatic sound volume correction.

In the third example, both of the upper-limit correction gain and the lower-limit correction gain are set, but one thereof may be set to limit the gain level range.

In the above description, the first to third examples of the live sound level correction gain generator 40 are individually provided to generate the gain control signal Gs for the main live sound signal. However, four types of the example where the fixed gain “1” is set for the main live sound signal in the first embodiment and the first to third examples of the live sound level correction gain generator 40 may be provided in the sound volume corrector 18 and may be switched.

As the switching method, the following automatic switching method may be employed in addition to a method of allowing a user to manually switch the types by the use of a switching operation unit provided as an operation means.

For example, an automatic switching method using EPG (Electronic Programming Guide) information included in the television broadcast signal can be employed. That is, a table in which the optimal methods of the four types of the live sound level correction gain generators 40 are correlated with genres such as drama, sports, and variety is prepared. Then, the EPG information is detected from the television broadcast signal, the genre of a broadcast program is detected, and the optimal live sound level correction gain generating method out of the four types is determined and set with reference to the table.

For example, identification information for specifying the optimal live sound level correction gain generating method out of the four types is previously recorded in DVD contents. On the other hand, a DVD player stores the correlation information of the identification information with the four-type live sound level correction gain generating methods. At the time of reproducing the DVD contents, the DVD player acquires the identification information from the DVD and determines what live sound level correction gain generating method should be used by referring to the correlation information on the basis of the acquired identification information.

By including the identification information for specifying the live sound level correction gain generating methods for the broadcast programs as part of the EPG information, it can be similarly determined what live sound level correction gain generating method should be used for the television broadcast program.

### Other Embodiments

### Other Separation Examples

In the first and second embodiments, the main first component signal is the main voice signal and the signal containing other components as a main component is the main live sound signal. However, the invention is not limited to this separation method. For example, an input audio signal may be separated into a middle-band component and a band component other than the middle-band component and the gains of the respective components may be controlled in the first gain control way and the second gain control way different from each other.

In the above-mentioned embodiments, the audio signal includes two left and right channel input audio signals. However, the audio signal of which the sound volume should be corrected may be a monaural audio signal.

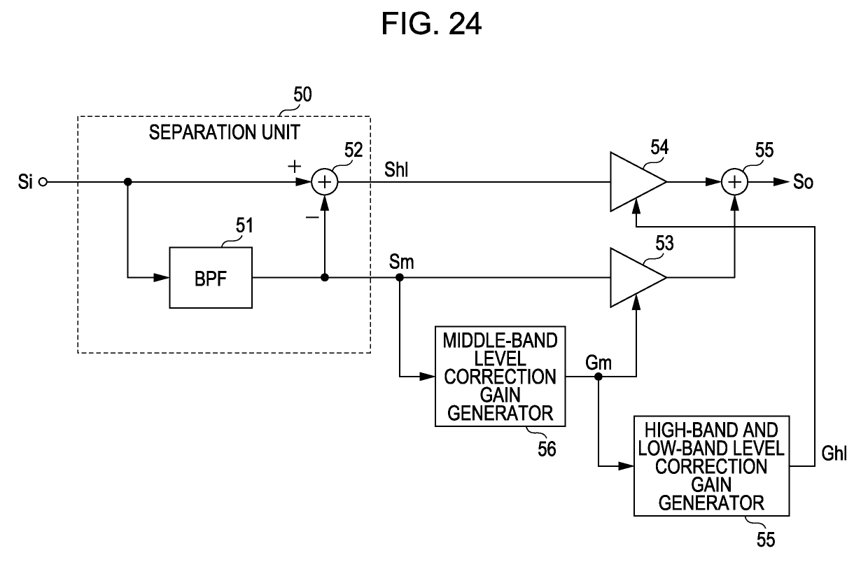

FIG. 24 shows another example of separating the input audio signal, where a monaural input audio signal is separated by the frequency bands. The example shown in FIG. 24 employs the second embodiment. The first embodiment may be employed.

That is, in a separation unit 50 in the example shown in FIG. 24, the monaural input audio signal Si is supplied to a band pass filter 51 extracting a middle-band component of an audio signal to acquire a main middle-band signal Sm containing only the middle-band component of the audio signal therefrom. The main middle-band signal Sm is supplied to a variable gain amplifier 53.

The main middle-band signal Sm from the band pass filter 51 is supplied to a subtractor 52 and is subtracted from the input audio signal Si, thereby acquiring a main high-band and low-band component signal Sh1 of the input audio signal Si. The main high-band and low-band component signal Sh1 is supplied to an adder 55 via the variable gain amplifier 54.

In this example, the main middle-band signal Sm from the band pass filter 51 is supplied to a middle-band level correction gain generator 56. The middle-band level correction gain generator 56 generates a gain control signal Gm for setting the output level of the main middle-band signal Sm to a constant level by detecting the average level of the main middle-band signal Sm and using the average level as a reference level. The gain control signal Gm is a middle-band level correction gain.

The middle-band level correction gain generator 56 supplies the generated gain control signal Gm to the variable gain amplifier 53, whereby the gain is controlled to maintain the output level of the main middle-band signal Sm at a constant level.

In this example, the gain control signal Gm generated by the middle-level correction gain generator 56 is supplied to a high-band and low-band level correction gain generator 57. Similarly to the second embodiment, the high-band and low-band level correction gain generator 57 generates a gain control signal Gh1 (high-band and low-band level correction gain) for the main high-band and low-band signals.

The high-band and low-band level correction gain generator 57 supplies the generated gain control signal Gh1 to the variable gain amplifier 54 to control the gain of the main high-band and low-band signal Sh1, similarly to the second embodiment.

In this way, an output audio signal So which is obtained by adding the main middle-band signal of which the gain is corrected in the first gain control way and the main high-band and low-band signals of which the gain is corrected in the second gain control way is obtained from the adder 55.

Therefore, in the example shown in FIG. 24, similarly to the above-mentioned embodiment, it is possible to correct the sound volume automatically so that the wobble in sound volume level due to the gain control is not marked.

As the example of separating the audio signals, various methods such as a method of separating the audio signals into two frequency bands of a high band and a low band can be employed in addition to the example shown in FIG. 24. The audio signals may be separated into three or more signal components, instead of two signal components. In this case, one of the three or more signal components may be controlled in gain in the first gain control way and the other signal components may be controlled in gain in the second gain control way, or the other signal components may be controlled in gain in two or more different gain control ways.

### Multi Channels

The audio signals may be multi channels of three or more channels such as 5.1 channel surround audio signals. In the multi channel, the input audio signal is separated in advance. When a center channel exists in the multi channels, the center channel may be used as the main voice signal in the above-mentioned embodiment.

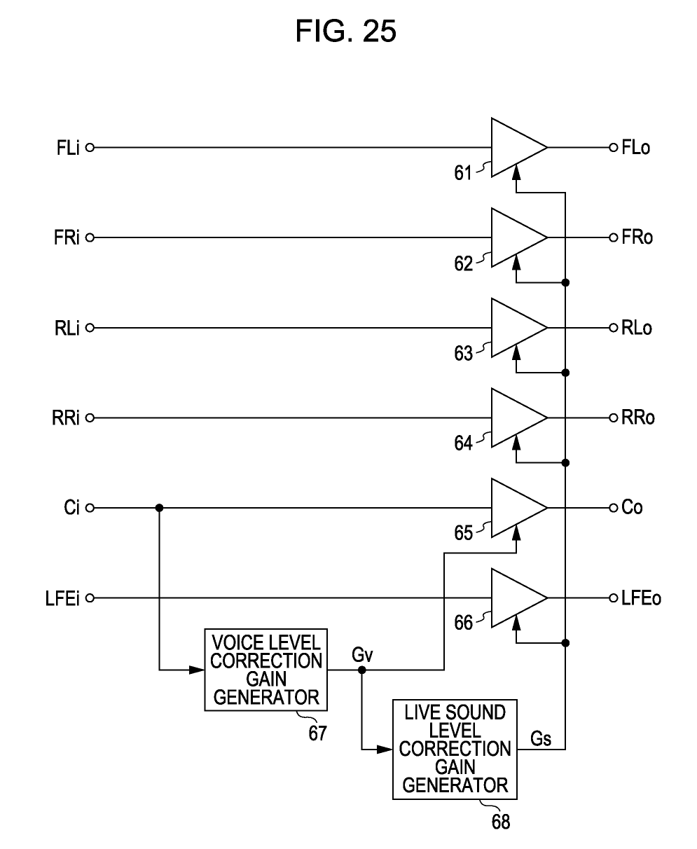

FIG. 25 is a diagram schematically illustrating the configuration of a sound volume correcting device when an input audio signal is a 5.1 channel surround audio signal.

In this example, front left and right channel audio signals FLi and FRi are supplied to variable gain amplifiers 61 and 62. Rear left and right channel audio signals RLi and RRi are supplied to variable gain amplifiers 63 and 64. A center channel audio signal Ci is supplied to a variable gain amplifier 65. A low-band audio signal LFE (Low Frequency Effect) is supplied to a variable gain amplifier 66.

The center channel audio signal Ci is supplied to a voice level correction gain generator 67. The voice level correction gain generator 67 has the same configuration as the voice level correction gain generator 30 shown in FIG. 14 and generates a gain control signal Gv. The gain control signal Gv generated by the voice level correction gain generator 67 is supplied to the center channel variable gain amplifier 65.

The gain control signal Gv generated by the voice level correction gain generator 67 is supplied to a live sound level correction gain generator 68. The live sound level correction gain generator 68 has the same configuration as the live sound level correction gain generator 40 shown in FIG. 14 and generates a gain control signal Gs. The gain control signal Gs generated by the live sound level correction gain generator 68 is supplied to a center-channel-excluded variable gain amplifiers 61 to 64 and 66.

The audio signals FLo, FRo, RLo, RRo, Co, and LFo are acquired from the variable gain amplifiers 61 to 66 and are output from speakers thereof.

In the example shown in FIG. 25, the center channel audio signal Ci out of the 5.1 channel input audio signals FLi, FRi, RLi, RRi, Ci, and LFi is controlled in gain in the first gain control way on the basis of the gain control signal Gv. On the other hand, the center-channel-excluded audio signals out of the 5.1 channel input audio signals FLi, FRi, RLi, RRi, Ci, and LFi are controlled in gain in the second gain control way different from the first gain control way on the basis of the gain control signal Gs.

The 5.1 channel output audio signals FLo, FRo, RLo, RRo, Co, and LFo are acoustically reproduced by individual speakers and acoustically combined, whereby the wobble in sound volume due to the first gain control way is reduced, thereby not causing an unpleasant feeling.

In the example shown in FIG. 25, the center-channel-excluded audio signals are all controlled in gain in the second gain control way on the basis of the gain control signal Gs, but may be controlled in gain in different gain control ways by channels. The center-channel-excluded audio signals may be grouped into two or more and may be controlled in gain in different gain control ways by groups.

The multi channel input audio signals of 5.1 channels may be mixed down and may be acoustically reproduced in two channels by two speakers. In this case, the first embodiment or the second embodiment can be applied to the mixed-down two channel input audio signals.

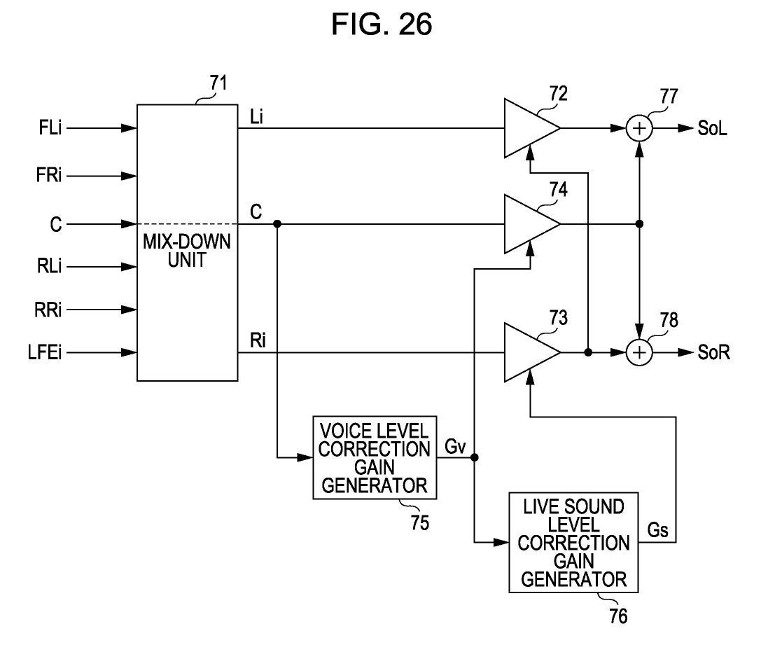

The mixing-down may be carried out by the configuration shown in FIG. 26 in which the gain is controlled using the center channel audio signal out of the 5.1 channel input audio signals.

FIG. 26 is a diagram schematically illustrating the configuration of a sound volume correcting device when the 5.1 channel surround audio signals are mixed down and the sound is output in two channels. The example shown in FIG. 26 is applied to the second embodiment, but may be applied to the first embodiment.

In the example shown in FIG. 26, the 5.1 channel surround audio signals FLi, FRi, RLi, RRi, Ci, and LFi are supplied to a mix-down unit 71 and are mixed down into two left and right channel audio signals Li and Ri. In this example, the mix-down unit 71 outputs the center channel audio signal Ci without any change.

The two left and right channel input audio signals Li and Ri from the mix-down unit 71 are supplied to variable gain amplifiers 72 and 73. The output signals of the variable gain amplifiers 72 and 73 are supplied to adders 77 and 78.

The center channel audio signal Ci from the mix-down unit 71 is supplied to a variable gain amplifier 74. The output signal of the variable gain amplifier 74 is supplied to the adders 77 and 78. The adders 77 and 78 output two channel output audio signals SoL and SoR.

The center channel audio signal Ci from the mix-down unit 71 is supplied to a voice level correction gain generator 75. The voice level correction gain generator 75 has the same configuration as the voice level correction gain generator 30 shown in FIG. 14 and generates a gain control signal Gv. The gain control signal Gv generated by the voice level correction gain generator 75 is supplied to the center-channel variable gain amplifier 74.

The gain control signal Gv generated by the voice level correction gain generator 75 is supplied to a live sound level correction gain generator 76. The live sound level correction gain generator 76 has the same configuration as the live sound level correction gain generator 40 shown in FIG. 14 and generates a gain control signal Gs. The gain control signal Gs generated by the live sound level correction gain generator 76 is supplied to the variable gain amplifiers 72 and 73.

The example shown in FIG. 26 has the same operational advantages as described above.

### Non-Real-Time Process

In the above-mentioned embodiments, the voice average level or voice-excluded average level of the audio input signals is detected and the gain is controlled, in real time. However, the invention is not limited to the real-time process.

For example, the gain control signal Gv or Gs for audio signals recorded in a recording medium may be generated and may be recorded to be correlated with recording signals. In this case, the sound volume of the reproducing audio signals can be controlled using the recorded gain control signal Gv or Gs at the time of reproducing the audio signals.

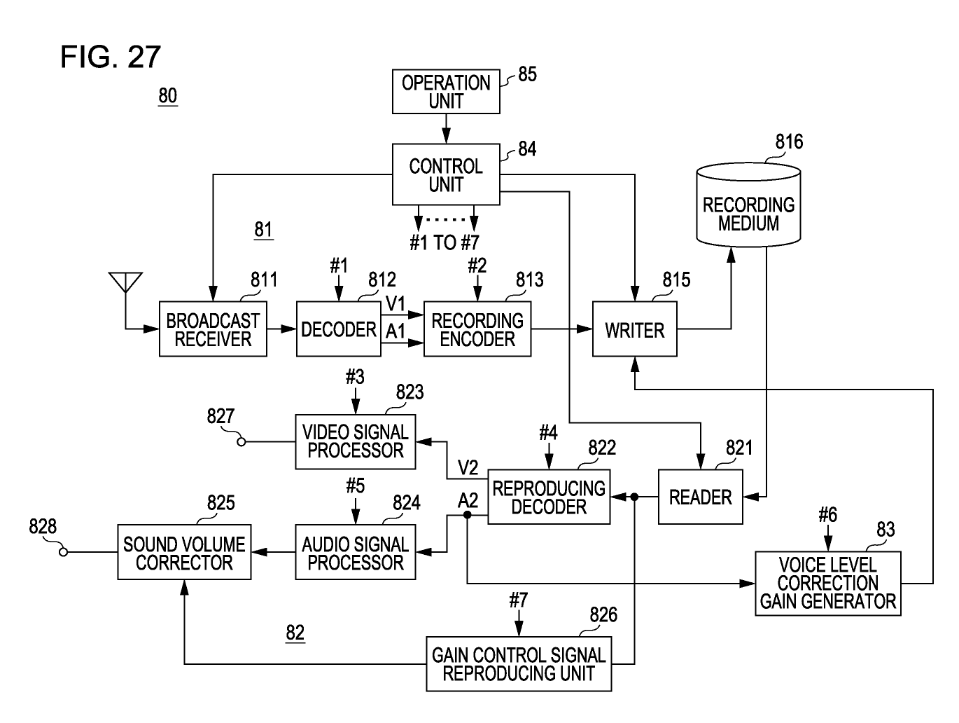

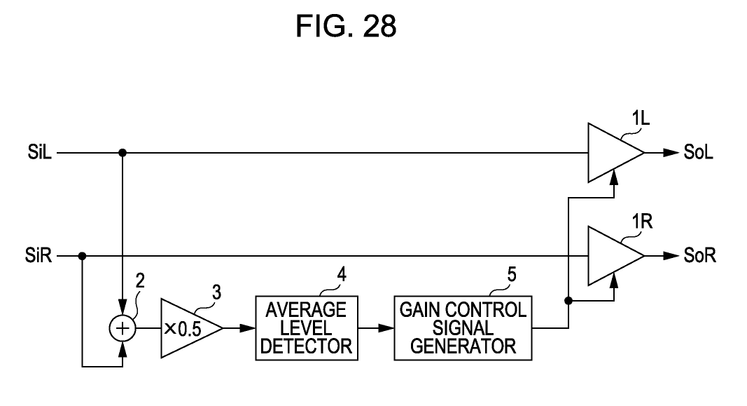

FIG. 27 is a block diagram illustrating an example where the invention is applied to a recording and reproducing apparatus recording television broadcast signals on a recording medium such as a hard disk or a DVD (Digital Versatile Disc).

The recording and reproducing apparatus 80 shown in FIG. 27 includes a broadcast recording system 81, a reproducing system 82, a level correction gain generator 83, a control unit 84, and an operation unit 85. The operation unit 85 includes, for example, a remote controller transceiver. The control unit 84 includes, for example, a micro computer and controls the units of the recording and reproducing apparatus 80 in accordance with the operation input from the operation unit 85.

In the first embodiment shown in FIG. 1, the level correction gain generator 83 includes a centered orientation signal detector 21 and a voice level correction gain generator 30. In the second embodiment shown in FIG. 14, the level correction gain generator includes a centered orientation signal detector 21, a voice level correction gain generator 30, and a live sound level correction gain generator 40.

When a user operates the operation unit 85 to give a recording instruction, the control unit 84 controls the broadcast recording system 81 to record the instructed broadcast program.

In the broadcast recording system 81, the broadcast receiver 811 receives broadcast wave signals of a broadcast program of which the recording is instructed and supplies the received broadcast signals to a decoder 812. In this example, a video signal V1 and an audio signal A1 are decoded from the received signal and are output by the decoder 812. Here, the audio signal A1 includes, for example, two left and right channel audio signals.

The video signal V1 and the audio signal A1 from the decoder 812 are encoded by a recoding encoder 813 and are recorded on a recording medium 816 by a writer 815. For example, a hard disk device is used as the recording medium 816.

In this example, the operation unit 85 is provided with a key for specifying broadcast program contents recorded on the recording medium 816 and a key for instructing the generation of a level correction gain. When a user specifies the recorded broadcast program contents and operates the key for instructing the generation of the level correction gain, the control unit 84 performs a level correction gain generating process properly to adjust the reproducing sound volume of the audio signals of the specified broadcast program contents.

That is, the control unit 84 controls a reader 821, a reproducing decoder 822, a level correction gain generator 83, and a writer 815 on the basis of the operation input of the key for instructing generation of the level correction gain.

The control unit 84 controls the reader 821 to read the recorded signals of the specified broadcast program from the recording medium 816. The reader 821 supplies the read recorded signals to the reproducing decoder 822. The reproducing decoder 822 decodes the recorded signals and outputs a reproducing video signal V2 and a reproducing audio signal A2.

The reproducing audio signal A2 from the reproducing decoder 822 is supplied to the level correction gain generator 83. The level correction gain generator 83 generates a gain control signal Gv or Gs as described in the first embodiment or the second embodiment.

The level correction gain generator 83 supplies the generated gain control signal Gv or Gs to the writer 815. The writer 815 records the gain control signal Gv or Gs from the level correction gain generator 83 on the recording medium 816 to be correlated with the recorded signals in reproduction under the control of the control unit 84.

When a user gives a reproduction instruction by the use of the operation unit 85, the control unit 84 controls the reproduction system 82 to reproduce the broadcast program of which the reproduction is instructed.

That is, the control unit 84 controls the reader 821 to read the recorded signal of the specified broadcast program and the gain control signal Gv or Gs correlated therewith from the recording medium 816. The reader 821 supplies the read recorded signals to the decoder 822 and supplies the read gain control signal Gv or Gs to the gain control signal reproducing unit 826.

The reproducing decoder 822 decodes the recorded signal and acquires the reproducing video signal V2 and the reproducing audio signal A2. The reproducing video signal V2 is output from a video input stage 827 via a video signal processor 823. A display unit is connected to an output stage 827 and a reproduced video of the broadcast program is displayed on the display screen thereof.

The reproducing audio signal from the reproducing decoder 822 is supplied to a sound volume corrector 825 via an audio signal processor 824. The sound volume corrector 825 has a configuration in which the voice level correction gain generator 30 is removed from the configuration according to the first embodiment shown in FIG. 1 or a configuration in which the voice level correction gain generator 30 and the live sound level correction gain generator 40 are removed from the configuration according to the second embodiment shown in FIG. 14.

On the other hand, the gain control signal reproducing unit 826 reproduces the gain control signal Gv or Gs from the signal from the reader 821. The gain control signal reproducing unit 826 supplies the reproduced gain control signal Gv or Gs to the sound volume corrector 825, whereby the gain is controlled as described in the above-mentioned embodiments. Therefore, an unpleasant feeling is not caused, similarly to the first embodiment and the second embodiment, even when the sound volume of the audio signal acquired from the sound volume corrector 825 is automatically corrected.

The reproducing audio signal from the sound volume corrector 825 is supplied to a speaker via an audio output stage 828.

In the example shown in FIG. 27, the level correction gain generator 83 has the same configuration as the first embodiment or the second embodiment. However, in the example shown in FIG. 27, since it is not necessary to perform a real-time process, the processing time increases but the degree of precision is enhanced.

For example, when the recording and reproducing apparatus 80 has sufficient buffer capacity and processing capability, the main voice signal including a human voice may be detected by detecting the pitch while taking the auto-correlation of the audio signal. By performing a spectrum envelope cepstrum analysis using an FFT (Fast Fourier Transform), the main voice signal including a human voice may be detected with higher precision.

In the non-real time process of the example shown in FIG. 27, the gain control signal Gv or Gs is generated and is correlated and recorded with the recorded signals. However, the audio signals of the recorded signals may be subjected to a sound volume correcting process based on the above-mentioned gain control and then the audio signals having been subjected to the sound volume correcting process may be recorded (rewritten) on the recording medium. In this case, it is possible to control the gain of the audio signals using the above-mentioned configuration with high precision.

The example shown in FIG. 27 discloses the recording and reproducing apparatus generating the gain control signal for the audio signals in a non-real time process. However, a recording and reproducing apparatus performing a sound volume correcting process in real time by applying the first embodiment or the second embodiment to the audio signals to be recorded may be constructed.

In this case, the recording and reproducing apparatus performs the sound volume correcting process in real time by applying the first embodiment or the second embodiment to the audio signals decoded by the decoder 812. The audio signals corrected in sound volume are recorded by the use of the recording encoder 813. In such a recording and reproducing apparatus, since it is not necessary to record the gain control signal Gv or Gs in correlation with the recorded signals, the level correction gain generator 83 is not necessary. It is also not necessary to provide the level correction gain reproducing unit 826 or the sound volume corrector 825 to the reproduction system 82.

### Other Embodiments and Modified Examples

In the first and second embodiments, the voice level correction gain generator 30 sets the output level of the main voice signal to a constant level by setting the average level of the main voice signal as a reference value. However, in the gain control way for the main voice signal, the gain may be controlled in such a manner that the total level of the input audio signals is set as the reference level.

In the second embodiment, the gain control way is changed by supplying the output gain control signal Gv from the voice level correction gain generator 30 to the live sound level correction gain generator 40 and performing an addition process on the gain control signal Gv. However, it is not necessary to make the first gain control way and the second gain control way have this dependent relation. The first gain control way for the main first component signal and the second gain control way for main component signals other than the first component are not particularly limited, as long as they are different from each other as described in the above-mentioned examples.

As described in the different methods of separating the audio signals in the separation unit, the main voice signal is an example of the main first component signal and the main live sound signal is an example of the main component signals other than the first component. The main first component signal and the main component signals other than the first component may be various other signals in the input audio signals. For example, one channel of the multi channels may be the main first component signal and other channels may be the main component signals other than the first component.

In the above description, the centered orientation signal detector 21, the voice level correction gain generator 30, and the live sound level correction gain generator 40 are constructed by hardware such as discrete circuit portions. However, they may be constructed by a DSP (Digital Signal Processor).

The centered orientation signal detector 21, the voice level correction gain generator 30, and the live sound level correction gain generator 40 may be constructed by software such as computer programs. In this case, in the example shown in FIG. 2, the voice level correction gain generator 30 or the live sound level correction gain generator 40 are provided as software processing functions to the control unit 10. As indicated by the dotted line in FIG. 2, the gain of the variable gain amplifier of the sound volume corrector 18 is controlled on the basis of the gain control signal from the control unit 10.

When an audio signal is processed by a digital signal processing method, all the units of the sound volume corrector 18 including the variable gain amplifier may be embodied by software.

The electronic apparatus employing the sound volume correcting device according to the embodiments of the invention is not limited to the television broadcast receiver shown in FIG. 2.

The present application contains subject matter related to that disclosed in Japanese Priority Patent Application JP 2008-310901 filed in the Japan Patent Office on Dec. 5, 2008, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A sound volume correcting device comprising:
first component gain control means for controlling a gain of a main first component signal, which contains a part of a plurality of audio components as a main component, out of input audio signals including the plurality of audio components and outputting the main first component signal;
first component gain control signal generating means for generating a first component gain control signal for allowing the first component gain control means to control the gain of the main first component signal in a first gain control way; and
other component output means for outputting other audio components other than the first component of the input audio signals in a second gain control way different from the first gain control way.

2. The sound volume correcting device according to claim 1, wherein the other component output means outputs the other audio components other than the first component with an unchanged output level.

3. The sound volume correcting device according to claim 1, wherein the other component output means includes:
other component gain control means for controlling the gain of the other audio components other than the first component and outputting the controlled other audio components; and
other component gain control signal generating means for generating another component gain control signal, which is used to allow the other component gain control means to control the gain of the other audio components other than the first component in the second gain control way, from the first gain control signal generated by the first gain control signal generating means.

4. The sound volume correcting device according to claim 1, wherein the first component gain control signal generated by the first component gain control signal generating means serves to keep the output level of the main first component signal constant.

5. The sound volume correcting device according to claim 3, wherein the first component gain control signal generated by the first component gain control signal generating means serves to keep the output level of the main first component signal constant, and
wherein the other component gain control signal generating means outputs the other audio components other than the first component with an unchanged level when the correction gain value based on the first component gain control signal is inside a reference range, and adjusts a ratio of the correction gain value based on the other component gain control signal to the correction gain value based on the first component gain control signal into a predetermined value when the correction gain value based on the first component gain control signal is outside the reference range.

6. The sound volume correcting device according to claim 3, wherein the first component gain control signal generated by the first component gain control signal generating means serves to keep the output level of the main first component signal constant, and
wherein the other component gain control signal generating means generates the other component gain control signal with a time delay characteristic following the gain correction of the main first component signal based on the first component gain control signal.

7. The sound volume correcting device according to claim 6, wherein the other component gain control signal generating means fixes the correction gain value based on the other component gain control signal to a set value when the correction gain value based on the other component gain control signal is greater than the set value which is obtained by multiplying the correction gain value based on the first component gain control signal by a predetermined reference value.

8. The sound volume correcting device according to claim 1, wherein an added output signal which is obtained by adding the output signal of the other component output means to the output signal of the first component gain control means is output as a volume-corrected sound volume output signal.

9. The sound volume correcting device according to claim 1, further comprising:
first separating means for separating the main first component signal from the input audio signal and supplying the separated main first component signal to the first component gain control means;
second separating means for separating a main second component signal, which contains other audio components other than the first component as a main component, from the input audio signal by subtracting the main first component signal from the input audio signal and supplying the separated main second component signal to the other component output means; and
adding means for adding the output signal of the other component output means to the output signal of the first component gain control means and outputting the added output signal as a volume-corrected output signal.

10. The sound volume correcting device according to claim 1, wherein the input audio signals include a plurality of channels of audio signals, and
wherein the main first component signal is a channel for a signal out of the plurality of channels of audio signals.

11. The sound volume correcting device according to claim 1, wherein the main first component signal contains a voice signal as a main component.

12. The sound volume correcting device according to claim 10, wherein the main first component signal is a center channel for a signal.

13. The sound volume correcting device according to claim 2, wherein the first component gain control signal generated by the first component gain control signal generating means serves to keep the output level of the main first component signal constant.

14. The sound volume correcting device according to claim 3, wherein the first component gain control signal generated by the first component gain control signal generating means serves to keep the output level of the main first component signal constant.

15. A sound volume correcting method comprising the steps of:
controlling a gain of a main first component signal, which contains a part of a plurality of audio components as a main component, out of input audio signals including the plurality of audio components in a first gain control way and outputting the gain-controlled main first component signal; and
controlling a gain of other audio components other than the first component out of the input audio signals in a second gain control way different from the first gain control way and outputting the gain-controlled other audio components.

16. An electronic apparatus employing a sound volume correcting device, the sound volume correcting device comprising:
first component gain control means for controlling a gain of a main first component signal, which contains a part of a plurality of audio components as a main component, out of input audio signals including the plurality of audio components and outputting the main first component signal;
first component gain control signal generating means for generating a first component gain control signal for allowing the first component gain control means to control the gain of the main first component signal in a first gain control way; and
other component output means for outputting other audio components other than the first component of the input audio signals in a second gain control way different from the first gain control way.

17. A sound volume correcting device comprising:
a first component gain control unit configured to control a gain of a main first component signal, which contains a part of a plurality of audio components as a main component, out of input audio signals including the plurality of audio components and outputting the main first component signal;
a first component gain control signal generator configured to generate a first component gain control signal for allowing the first component gain control unit to control the gain of the main first component signal in a first gain control way; and
another component output unit configured to output other audio components other than the first component of the input audio signals in a second gain control way different from the first gain control way.

18. An electronic apparatus employing a sound volume correcting device, the sound volume correcting device comprising:
a first component gain control unit configured to a gain of a main first component signal, which contains a part of a plurality of audio components as a main component, out of input audio signals including the plurality of audio components and outputting the main first component signal;
a first component gain control signal generator configured to generate a first component gain control signal for allowing the first component gain control unit to control the gain of the main first component signal in a first gain control way; and
an other component output unit configured to output other audio components other than the first component of the input audio signals in a second gain control way different from the first gain control way.
